(19) United States
(12) Patent Application Publication
(10) Pub. No.: US 2026/0088203 A1
(43) Pub. Date: Mar. 26, 2026

(54) MAGNET STRUCTURES

(71) Applicant: NANALYSIS CORP., Calgary, Alberta (CA)

(72) Inventors: Mark ELLIOT, Calgary, Alberta (CA); Neal GALLAGHER, Calgary, Alberta (CA); Amro HUSSEIN, Calgary, Alberta (CA); Garett LESKOWITZ, Calgary, Alberta (CA); Anish PATEL, Calgary, Alberta (CA); Adam PAULSON, Calgary, Alberta (CA); Colten WRIGHT, Calgary, Alberta (CA)

(73) Assignee: NANALYSIS CORP., Calgary, Alberta (CA)

(21) Appl. No.: 19/111,652

(22) PCT Filed: Sep. 15, 2023
(86) PCT No.: PCT/CA2023/051235

§ 371 Date: Mar. 13, 2025

Related U.S. Application Data
(60) Provisional application No. 63/407,500, filed on Sep. 16, 2022.

(51) Int. Cl. H01F 7/02; G01R 33/383; H01F 41/02

(52) U.S. Cl. CPC H01F 7/0278; H01F 41/0253; G01R 33/383

(57) ABSTRACT

Disclosed are a magnet-insert assembly adapted for insertion into and removal from a central cavity of a magnetic-field generating magnet array, and a magnet array adapted to receive the magnet-insert assembly. The magnet insert assembly comprising a substructure defining a shaft therein; one or more headstones; and one or more permanent magnets. The substructure being adapted to receive, secure and position the one or more headstones and the one or more permanent magnets in the central cavity of the magnet array.

### CROSS-REFERENCE TO RELATED APPLICATIONS

This application is a National Stage Application of International Application No. PCT/CA2023/051235, filed on Sep. 15, 2023, which claims the benefit of U.S. Provisional Application Ser. No. 63/407,500, filed on Sep. 16, 2022, and which applications are incorporated herein by reference. To the extent appropriate, a claim of priority is made to each of the above disclosed applications.

### TECHNICAL FIELD

The subject matter disclosed generally relates to magnet structures. More particularly, it relates to modified Halbach magnet configurations and ancillary magnetic apparatuses.

### PRIOR ART

In a nuclear magnetic resonance (NMR) experiment, a sample for analysis is placed under the influence of a biasing static magnetic field, which partially aligns the sample's nuclear-spin magnetic moments. The moments precess in the static field at a frequency, called the Larmor frequency, which is proportional to the field strength. The magnetic moments of the sample can be manipulated by applying a transverse radio frequency (RF) magnetic field at the Larmor frequency. By observing the reaction of the sample to the RF field, insight into the chemical composition of the sample can be gained. The power of NMR as an analytical method may be largely a function of how well the characteristics of the applied magnetic fields can be controlled.

The practice of shimming magnetic fields (rendering the fields more uniform) has existed since the earliest days of NMR and originally used thin pieces of metal physically placed behind source magnets to adjust the positions of those magnets to refine the magnetic field. More modern shimming techniques use electro-magnetic coils. Conventional high-field magnetic resonance spectrometers commonly use shimming coils disposed on substantially cylindrical coil forms. In contrast, the use of shimming (shim) coils in compact NMR devices has proved difficult primarily due to space restrictions that may not accommodate traditional shim coil systems, which can have many layers. The space available inside a main magnet in many such devices may be too small to accommodate a typical set of shimming coils whose individual elements are each designed predominantly to address one and only one geometrical aspect or geometrical component of the residual inhomogeneity of the main magnetic field.

FIGS. 1A, 1i, and 1C compare the main biasing field and sample tube configurations of typical high-field spectrometer designs with a design for compact magnet systems that is based on a cylindrical Halbach array. The arrows labelled B indicate the main magnetic field direction. No shimming measures are shown in the figures. FIG. 1A schematically shows the superconducting field coils of the high-field magnet, an inserted cylindrical sample tube, and the field, B, produced by the coils. The magnetic field within the sample volume is aligned along the common symmetry axis of the coils and the tube.

FIGS. 1B and 1C show the same sample tube inserted into a cylindrical Halbach magnet array, which produces a field, B, perpendicular to the symmetry axis of the tube. This particular Halbach array is composed of eight magnets in a circular (as shown in FIG. 1B) arrangement placed around the tube, with the magnetization vectors of the magnets (shown as arrows) perpendicular to the tube's symmetry axis. The magnetization vector is a quantitative and directional representation of the polarization of magnetic dipoles in a material. The field inside the Halbach array is quite uniform for some applications but can be too inhomogeneous for some high-resolution NMR experiments.

In order to substantially reduce the inhomogeneity of a magnetic field, it may be helpful to have independent control over different geometrical aspects of the field inhomogeneity. In many magnetic resonance applications, the main magnetic field is strongly polarized along a specified direction. Within this application, as is common practice in the art, this direction is understood to be the z-axis in a Cartesian reference frame in which the origin is at some fixed point, for example near the center of a sample under study. The Larmor frequency of magnetic spins located at a point in space is determined by the magnitude of the field at that point, which in reasonably homogeneous fields is very well approximated by the z-component of the field, B_{z}. One can expand B_{z} as a scaled sum of functions,

$${B}_{z} ( x , y , z ) = {B}_{0} + {\sum }_{k} {c}_{k} {f}_{k} ( x , y , z ) ,$$

where k is a variable (or a number of variables) used to index the various functions, fₖ, in the set, and where x, y, and z are Cartesian or other spatial coordinates defining positions within a volume enclosing at least part of the sample. B₀ is the large and spatially uniform part of the field, and the coefficients, cₖ, quantify different components of the field inhomogeneity. Such sets of functions, for example x, z, xy, (x²−y²) are said to be orthogonal (with respect to a specified scalar product of functions) if the scalar product between two functions that are not the same is zero. A common scalar product between two functions is the integral,

$$〈 {k}_{1} \vert {k}_{2} 〉 = {\int }_{V}^{} W ( x , y , z ) {f}_{{k}_{1}} ( x , y , z ) {f}_{{k}_{2}} * ( x , y , z ) dV ,$$

where V denotes a volume relevant to the functions over which the integral is calculated, where the star denotes complex conjugation, and where W denotes a weighting function defined on the volume, which quantifies how important the volume element at (x, y, z) is in its contribution to the integral.

Well-controlled magnetic fields are particularly important in nuclear magnetic resonance (NMR) spectroscopy and other magnetic resonance (MR) applications. In many NMR spectroscopy experiments, a strong, static magnetic field is applied in a region of space that contains a sample under study, and it is desirable that this field be as spatially uniform as possible in order to observe important but subtle variations in the magnetic response of the sample. It is also desirable in many NMR applications to have a static magnetic field that is as strong as is practical.

At least three classes of magnets have been used to provide strong, static magnetic fields in NMR devices: superconducting electromagnets, resistive electromagnets, and permanent magnets. Permanent magnets or arrays (also called assemblies or configurations) thereof can be advantageous in applications where low cost, low maintenance and/or portability are desirable. A particularly useful design for compact applications is a permanent magnet assembly based on Halbach cylinders, which comprise component magnets oriented and arranged around a central bore (sometimes referred to as a central volume, central space, central channel or central cavity) in the magnet array.

In practice, permanent magnets are often accompanied by pole pieces, which are pieces of magnetically permeable material placed in the vicinity of magnets in order to contribute to or shape a magnetic field. In some applications, it is desirable that materials used for pole pieces be magnetically “soft,” that is, that they have a relatively low coercivity. It is also desirable in some applications that pole piece materials be strongly magnetized when placed in a magnetic field, that is, that they have a high saturation magnetization. In the present disclosure, we will refer to such materials as “magnetically permeable,” a designation that is standard and well understood in the art.

One design for producing a substantially strong magnetic field in a small volume is the Halbach cylinder, wherein magnetic dipoles within high-coercivity permanent magnet materials are arranged around a central cavity. FIG. 2 shows a cross-sectional view of an idealization of a Halbach cylinder 10, along with a coordinate system 12 that is used to compute and select the orientations of magnetic dipoles, shown as arrows 14, within a region surrounding a central volume 16. In the idealized Halbach cylinder, magnetization direction \hat{m} is position-dependent according to the equation,

$$\hat{m} ( ρ , ϕ , x ) = cos ( k ϕ ) \hat{ρ} + sin ( k ϕ ) \hat{ϕ} ,$$

in cylindrical polar coordinates ρ, φ, x, with integer parameter k=1 for the most prevalent case, which produces a substantially uniform field in the central volume 16. Other choices of k provide different, non-uniform field configurations. In practical implementations, discrete component magnets are used as an approximation to the continuously varying magnetization suggested by FIG. 2.

FIGS. 3A, 3B, 3C and 3D show example prior art implementations of Halbach-cylinder-based magnet configurations. FIG. 3A (adapted from F. Bertora, A. Trequattrini, M. G. Abele, and H. Rusinek, “Shimming of yokeless permanent magnets designed to generate uniform fields,” Journal of Applied Physics 73, 6864, 1993) shows a cylindrical configuration of magnets designated 20 surrounding space 24, that makes efficient use of space and employs many oblique shapes 21, 22, 23 in its design.

FIG. 3B (adapted from E. Danieli, J. Mauler, J. Perlo, B. Blumich, and F. Casanova, “Mobile sensor for high resolution NMR spectroscopy and imaging, Journal of Magnetic Resonance 198, 80, 2009) shows an array 30 that uses permanent magnets of the same cubic shape 31 to enclose space 32. However, this implementation suffers from low packing density.

When the space surrounding a central volume is broken up into regions, the individual component magnets placed therein may exhibit oblique shapes, such as those shown in FIG. 3A, that are difficult or expensive to fabricate with high tolerance. The magnetizations required within the component magnets may also be difficult to control with precision sufficient to ensure the quality of the magnetic field within the central volume. If, instead, simpler component magnets such as cubes are used, as in FIG. 3B, these can be fabricated and magnetized with high precision straightforwardly, but the geometrical constraints for some designs can result in a low packing density, with an attendant reduction in the field strength that can be produced.

FIG. 3C is a cross section of an embodiment of a Halbach cylinder 40 comprising an array of closely packed hexagonal prisms 41 surrounding central space 42, disclosed in U.S. Pat. No. 8,712,706 to Leskowitz, et al., incorporated herein by reference in its entirety. FIG. 3D (also disclosed in U.S. Pat. No. 8,712,706), shows the general arrangement 50 of individual main magnets 52 in a magnet array around a central cavity 53 in which pole pieces 54 and a sample 56 are positioned. FIG. 3D also illustrates the positioning of shim panels 58 on the pole pieces 54. Arrows 59 show the predominant magnetization directions of each main magnet 52 in the arrangement.

In a Halbach cylinder model, the ideal is an infinitely long cylinder. In practice, the cylinder is of finite length, which can lead to various technical problems and undesirable features in the primary magnetic field of the array, and designs attempting to overcome these disadvantages can be complex. An alternative approach for producing homogeneous fields uses a Halbach sphere, practical embodiments of which have been suggested by H. Leupold in US paten t no. 4,837,542.

FIG. 4A, adapted from U.S. Pat. No. 9,952,294 to Leskowitz, incorporated herein by reference in its entirety, shows a sphere 60 enclosing a central cavity 62 and having local magnetic dipole orientations 64. Once a desired magnetic field axis, \hat{v}, is selected, the required magnetization directions for the component magnets in the assembly can be calculated by establishing a spherical polar coordinate system 66 with colatitude angle θ=0 along the magnetic field direction \hat{v}, then calculating the magnetization direction in for the given magnet's center coordinates according to formulas disclosed in U.S. Pat. No. 9,952,294 to Leskowitz.

In order to best approximate a uniform field in the idealized case, magnetization direction \hat{m} within the spherical shell surrounding the central cavity is position-dependent according to the equation,

$$\hat{m} ( r , θ , φ ) = cos ( k θ ) \hat{r} + sin ( k θ ) \hat{θ} ,$$

in spherical polar coordinates r, θ, φ, again with parameter k=1 for the uniform-field case.

It will be observed that magnetization in the spherical case differs from the magnetization in the cylindrical case. In the Halbach sphere model, the magnetization of the dipole at a position \vec{r}=r\hat{r} lies in the meridional plane spanned by \hat{r} and \hat{θ}, but in the Halbach cylinder model, the magnetization lies in a plane spanned by \hat{ρ}=(r\hat{r}−z\hat{z})/p, the unit vector directed away from the cylindrical symmetry axis, and \hat{φ}, the azimuthal unit vector. In the idealized Halbach cylinder case, the magnetization direction has no \hat{x}component (along the cylindrical symmetry axis) and is independent of the x coordinate of the dipole's position. A variety of numerical representations of such position-dependent magnetizations are possible and will be readily identified and understood.

Spherical assemblies can be composed of combinations of magnets having complex shapes, as illustrated in FIG. 4B (adapted from U.S. Pat. No. 4,837,542 to Leupold). In FIG. 4B it will be seen that the sphere 70 comprises multiple component primary magnets 72 having chosen dipole orientations 74 and surrounding central cavity 76. In order to achieve the desired configuration and field, a large number of different primary magnets having different shapes and magnetic orientations is required. Again, these can be challenging or impractical to fabricate with high tolerance.

Magnet arrays and methods for generating magnetic fields are disclosed in U.S. Pat. No. 9,952,294 to Leskowitz, including a magnet array comprising a plurality of polyhedral magnets arranged in a lattice configuration and at least partly enclosing a testing volume, the magnet array having an associated magnetic field with a designated field direction \hat{v}, wherein the magnetization direction \hat{m} of an individual polyhedral magnet located at a displacement vector \vec{r} from an origin point in the testing volume is determined by the formula:

$$\hat{m} = ( 2 ( \hat{v} \cdot \vec{r} ) \hat{r} - ( \vec{r} \cdot \vec{r} ) \hat{v} ) / ( \vec{r} \cdot \vec{r} ) .$$

As illustrated in FIG. 4C (adapted from U.S. Pat. No. 9,954,294 to Leskowitz), magnet array 100 is based on a simple cubic lattice and polyhedral magnets 101 are truncated cubes. Further, some of the polyhedral magnets 101 comprised in the lattice configuration making up the magnet array 100 are larger first magnets 103 and others are smaller second magnets 106. The smaller second magnets 106 form composite magnets 104 at particular sites in the array. As will be seen in FIG. 4C, the use of such smaller second magnets 106 is exploited to provide a sample channel 107, in this case oriented along a body diagonal of the array.

In practice, a Halbach sphere configuration can produce a magnetic field that is larger than that produced by a Halbach cylinder configuration. However, Halbach sphere configurations can suffer from limited access to the central region of the magnet compared to Halbach cylinder configurations.

In applications such as magnetic resonance applications, it may be advantageous to use the largest magnetic fields that are practical. One way to increase the field present inside a Halbach cylinder magnet configuration is to insert pole pieces into the bore of the Halbach cylinder magnet configuration. U.S. Pat. No. 9,341,690 to Leskowitz and McFeetors discloses shaped pole pieces in a cylindrical Halbach magnet configuration.

Another way to increase the field present inside a Halbach cylinder magnet configuration is to increase the number of component magnets that are used to constitute the magnet configuration. Such component magnets may be configured in concentric ring structures. For example, FIG. 3D exhibits a single hexagonal ring of six magnets, and FIG. 3C exhibits a hexagonal ring of six magnets surrounded by a hexagonal ring of twelve magnets. It will be readily appreciated that each component magnet is subject to magnetic interaction with the total magnetic field generated by all the other magnets in an assembly. In particular, a component magnet may be located at a site where the total magnetic field generated by the other magnets is substantially aligned with the magnetization of said component magnet. In that case, said component magnet would be under relatively low coercive stress and would therefore be subject to a weak demagnetizing force. Conversely, a component magnet may be located at a site where the total magnetic field generated by the other magnets is substantially aligned away from or opposing the magnetization of said component magnet. In that case, said component magnet would be under relatively high coercive stress and would therefore be subject to a strong demagnetizing force. Mitigating or controlling demagnetizing forces is a critical issue in determining the stability and performance of magnet arrays in applications. Moreover, elevated coercivity can be associated with increased cost.

Another important consideration in applications, especially in high-resolution magnetic resonance, is the temporal stability of the magnetic field, that is, it is desirable to limit the fluctuations of magnetic field strength over time. These temporal fluctuations are strongly influenced when changes of temperature (thermal changes) are present. It is well known that the magnetization of permanent magnet materials is subject to variation with temperature. Indeed, a common specification of commercial grades of permanent magnet materials, including rare-earth permanent magnet materials, is their temperature coefficient (the fractional variation in magnetization strength), which can be on the order of 0.1% per degree Celsius. Such variation in strength can proportionately affect the magnetic field produced by the permanent magnets. Those applications which rely on a temporally stable magnetic field can be deleteriously affected by magnets that are strongly thermally coupled to variations in temperature of a sample or other components in a magnet array's central cavity.

There is therefore a need for magnet array designs which balance the need for high field with the desired increased internal space that can facilitate improved thermal isolation between a magnet array and an enclosed sample. Further, there remains a need for a solution that allows for increased magnetic fields while maintaining the low-cost, convenience, and manufacturability of cylindrical, spherical and modified Halbach magnet configurations.

### SUMMARY

According to one aspect, there is provided a magnet-insert assembly adapted for insertion into and removal from a central cavity in a magnetic-field generating magnet array, the magnet-insert assembly comprising:
a substructure defining a shaft therein;
one or more headstones; and
one or more permanent magnets;
the substructure adapted to receive, secure and position the one or more headstones and the one or more permanent magnets in the central cavity of the magnet array.

The magnet-insert assembly may comprise two headstones and four permanent magnets, the four permanent magnets each having a hexagonal prismatic shape.

In an embodiment, the substructure may be a single piece of material.

In an embodiment, the substructure may have multiple segments.

In an embodiment, the substructure may have five segments:
a cap;
a top segment;
a mid-upper segment;
a mid-lower segment; and
a bottom segment.

In an embodiment, the shaft may be adapted to receive a central cavity assembly comprising one or more pole pieces and a pole piece positioner.

The magnet-insert assembly may further comprise one or more pieces of magnetically permeable material, the magnetic polarization of which, when inserted into the magnet array, modifies the magnetic field generated by the magnet array.

In an embodiment, the pieces of magnetically permeable material are tablets or inserts.

In another embodiment, each of the two headstones comprises a rear face and a front face.

The magnet-insert may further comprise one or more tablets.

The magnet-insert may further comprise eight tablets.

In an embodiment, four tablets are positioned in each depression defined by each headstone front face.

In an embodiment, each of the two headstones comprising multiple parts.

In another embodiment, each of the two headstones comprises two cooperating parts, a first part, distal to the shaft, and a second part, proximal to the shaft, and a front face of the first part defining a depression adapted to receive the one or more tablets.

In an embodiment, each front face defines a plurality of apertures adapted to receive inserts.

In an embodiment, the plurality of apertures may be threaded and the inserts being screws.

In an embodiment, the cap may further comprise:
a magnetically shielded layer;
a thermally insulating layer; and
a thermally conductive layer.

In another aspect, there is provided a magnet array comprising a plurality of magnet racks, the magnet array defining a central cavity adapted to receive a removable magnet-insert assembly comprising: a substructure defining a shaft therein; one or more headstones; and one or more permanent magnets; the substructure being adapted to receive, secure and position the one or more headstones and the one or more permanent magnets in the central cavity of the magnet array.

The shaft may be adapted to receive a central cavity assembly comprising one or more pole pieces and a pole piece positioner.

In an embodiment, the substructure may comprise a cap and a substructure body; at least one headstone is aligned with at least one permanent magnet to define a sidewall with the permanent magnet; and the shaft extends through the cap and the substructure body parallel to the sidewall.

In an embodiment, the at least one headstone is aligned with and provided in between two permanent magnets to define the sidewall with the two permanent magnets.

In another embodiment, each of two headstones are provided in between two permanent magnets to define a separate sidewall whereby the magnet-insert assembly comprises two sidewalls and the two sidewalls are symmetrically provided with respect to the shaft.

According to another aspect, there is provided a magnetic resonance device comprising a magnet array comprising a plurality of magnet racks, the magnet array defining a central cavity adapted to receive a removable magnet-insert assembly comprising:
a substructure defining a shaft therein;
one or more headstones; and
one or more permanent magnets; and
the substructure adapted to receive, secure and position the one or more headstones and the one or more permanent magnets in the central cavity of the magnet array.

According to another aspect, there is provided a method for assembling a magnet-insert assembly, comprising: providing a substructure defining a shaft therein; and arranging one or more headstones and one or more permanent magnets in the substructure.

According to another aspect, there is provided a method for assembling a magnet array, comprising:
providing a first plurality of polyhedral magnets;
arranging the first plurality of polyhedral magnets in a Halbach cylinder configuration in a magnet rack, the centers of individual ones of the plurality of polyhedral magnets being arranged substantially in a plane in the magnet rack, the first plurality of polyhedral magnets at least partly enclosing a central cavity in the magnet array;
providing a second plurality of polyhedral magnets;
arranging the second plurality of polyhedral magnets in a non-Halbach cylinder configuration in the magnet rack;
providing a plurality of truncated polyhedral magnets;
arranging the plurality of truncated polyhedral magnets in closest proximity to the central cavity; and
arranging the magnet rack in a rack stack to assemble the magnet array.

According to another aspect, there is provided a magnet rack comprising a cell framework surrounding a central cavity, the cell framework defining a plurality of lattice sites for receiving a plurality of magnets; wherein centers of the magnets occupying said lattice sites are arranged in a hexagonal Bravais lattice configuration; wherein the lattice sites define a plurality of concentric rings around the central cavity; wherein a shape of the central cavity is defined by the lattice sites of at least the innermost ring and the second innermost ring; and wherein a surface of each of a subset of magnets in the innermost ring is truncated.

According to another aspect, there is provided a magnet-insert assembly for removable insertion into a central cavity of a magnetic-field generating magnet array, the magnet-insert assembly comprising:
a substructure defining a cap and substructure body;
at least two permanent magnets;
at least one headstone aligned with and provided in between the two permanent magnets to define a sidewall with the two permanent magnets; and
a shaft extending through the cap and the substructure body parallel to the sidewall.

According to another aspect, there is provided a magnet-insert assembly for removable insertion into a central cavity of a magnetic-field generating magnet array, the magnet-insert assembly comprising:
one or more permanent magnets;
one or more headstones; and
a substructure adapted to receive, secure and position the one or more headstones and the one or more permanent magnets in the central cavity of the magnet array, the substructure defining a cap and substructure body;
wherein at least one headstone is aligned with at least one permanent magnet to define a sidewall with the permanent magnet; and
wherein a shaft is provided which extends through the cap parallel to the sidewall.

The magnet-insert assembly may further comprise two permanent magnets, wherein the headstone is aligned with and provided in between the two permanent magnets to define the sidewall.

The magnet-insert assembly may further comprise four permanent magnets and two headstones, wherein each headstone is provided in between two permanent magnets to define a separate sidewall whereby the magnet-insert assembly comprises two sidewalls.

In an embodiment, the two sidewalls are symmetrically provided with respect to the shaft.

Features and advantages of the subject matter hereof will become more apparent in light of the following detailed description of selected embodiments, as illustrated in the accompanying figures. As will be realized, the subject matter disclosed and claimed is capable of modifications in various respects, all without departing from the scope of the claims. Accordingly, the drawings and the description are to be regarded as illustrative in nature, and not as restrictive and the full scope of the subject matter is set forth in the claims.

### BRIEF DESCRIPTION OF THE DRAWINGS

Further features and advantages of the present disclosure will become apparent from the following detailed description, taken in combination with the appended drawings, in which:

FIG. 1A is a schematic side view showing a sample tube in a prior art arrangement of superconducting coils for producing a strong magnetic field aligned along a sample tube's symmetry axis;

FIG. 1B is a schematic top view showing a sample tube in a prior art cylindrical Halbach magnet array viewed along the symmetry axis of the tube;

FIG. 1C is a schematic perspective view showing a sample tube in a prior art cylindrical Halbach magnet array viewed along an axis perpendicular to the symmetry axis of the tube;

FIG. 2 is a cross-sectional view of a prior art idealized Halbach cylinder;

FIGS. 3A-3C are cross-sectional views of implementations of prior art Halbach-cylinder-based magnet assemblies;

FIG. 3D shows a prior art arrangement of pole pieces and shim panels inside a central cavity within a Halbach cylinder magnet array;

FIG. 4A depicts a prior art idealized magnetization scheme for a Halbach sphere;

FIG. 4B shows a practical prior art embodiment of a Halbach sphere;

FIG. 4C is a corner view of a prior art embodiment of a magnet assembly based on a lattice configuration of polyhedral magnets;

FIG. 5 shows a top view of an embodiment of a magnet array;

FIG. 6 shows a perspective view of an embodiment of a magnet rack stack comprising five magnet racks;

FIG. 7A shows different types of hexagonal prismatic magnets having different magnetization vectors;

FIG. 7B is a diagram of top and side views of a truncated hexagonal prismatic magnet;

FIG. 8 shows a block diagram of a magnetic resonance device including a magnet array, in accordance with an embodiment of the disclosure;

FIG. 9 shows a top view of another embodiment of a magnet array;

FIG. 10A shows an exploded view of an embodiment of multiple magnet racks in a rack stack;

FIG. 10B shows the top view of the embodiment of FIG. 5 with radial ring coordinate labels added;

FIG. 10C shows the top view of the embodiment of FIG. 5 and FIG. 10B with azimuthal coordinate labels added;

FIG. 11A shows a top view of yet a further embodiment of a magnet array;

FIG. 11B shows a top view of part of the embodiment of FIG. 11A;

FIG. 11C shows a side view of part of magnet racks+1, 0 and −1 of the embodiment of FIGS. 11A and 11B;

FIG. 12A shows an exploded view of yet an even further embodiment of a magnet array;

FIG. 12B shows a perspective view of the magnet array of FIG. 12A;

FIG. 12C shows a top view of a third (central) magnet rack of FIG. 12A;

FIG. 12D shows a top view of a second (and fourth) magnet rack of FIG. 12A;

FIG. 12E shows a top view of a fifth (bottom) magnet rack of FIG. 12A;

FIG. 13 shows a perspective view of an embodiment of a magnet array and a magnet-insert assembly before (or after) insertion of the magnet-insert assembly into the magnet array;

FIG. 14A shows an exploded view of an embodiment of a magnet array, a magnet-insert assembly and a central cavity assembly;

FIG. 14B shows a cross-sectional view of an assembled magnet array, magnet-insert assembly and central cavity assembly;

FIG. 14C shows a side view of the magnet array of FIG. 14B;

FIG. 14D shows a cross-sectional view of an assembled magnet array and a magnet-insert assembly;

FIG. 14E shows a further cross-sectional view of an assembled magnet array, magnet-insert assembly and central cavity assembly;

FIG. 15A shows a side view of a magnet-insert assembly;

FIG. 15B shows a further side view of a magnet-insert assembly;

FIG. 15C shows the side view of the magnet-insert assembly of FIG. 15A and a central cavity assembly positioned in the magnet-insert assembly;

FIG. 15D shows the further side view of the magnet-insert assembly of FIG. 15B and a central cavity assembly positioned in the magnet-insert assembly;

FIG. 15E shows a top view of the magnet-insert assembly of FIG. 15A and FIG. 15B;

FIG. 15F shows a top view of the magnet-insert assembly and central cavity assembly of FIG. 15C and FIG. 15D;

FIG. 16A shows a perspective view of a magnet-insert assembly with tablets;

FIG. 16B shows a perspective view of a magnet-insert assembly with threaded inserts;

FIG. 16C shows a perspective view of a magnet-insert assembly and central cavity assembly;

FIG. 17A shows an exploded view of the magnet-insert assembly of FIG. 16A;

FIG. 17B shows the exploded view of the magnet-insert assembly of FIG. 16A and a central cavity assembly;

FIG. 18A shows an exploded view of an alternative embodiment to the magnet-insert assembly of FIG. 16A;

FIG. 18B shows the exploded view of the alternative embodiment of FIG. 18A and a central cavity assembly;

FIG. 19A shows an exploded view of the magnet-insert assembly of FIG. 16B;

FIG. 19B shows the exploded view of the magnet-insert assembly of FIG. 19A and a central cavity assembly.

FIG. 20A shows a perspective view of an assembled cap of a substructure of a magnet-insert assembly; and

FIG. 20B shows an exploded view of the cap of FIG. 20A.

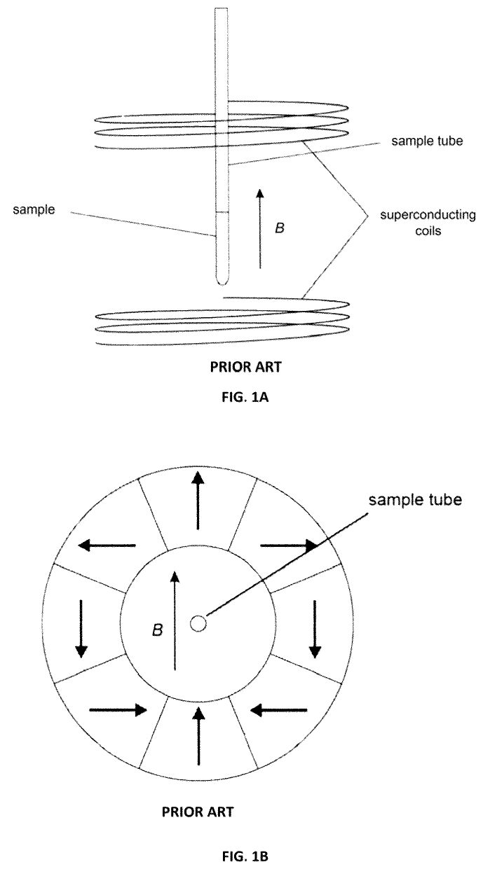

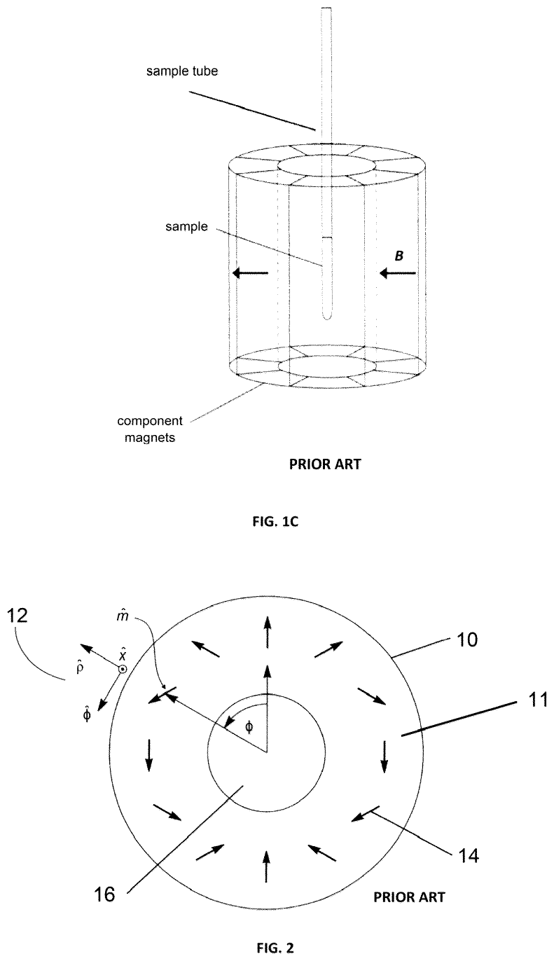

It will be noted that throughout the appended drawings, like features are identified by like reference numerals.

### DETAILED DESCRIPTION

In the present disclosure, the term Halbach cylinder configuration means a configuration of individual magnets (often called component magnets) disposed around a central volume containing an axis \hat{x}, in which the magnetization of each magnet is substantially oriented according to the equation

$$\hat{m} ( ρ , ϕ , x ) = cos ( k ϕ ) \hat{ρ} + sin ( k ϕ ) \hat{ϕ} ,$$

where ρ, φ, x, are the cylindrical polar coordinates of the center of said individual component magnet relative to an origin location and a preferred axis with φ=0, and where k is an integer parameter. A magnetization is “substantially oriented” along a direction if it is exactly oriented along that direction or if it is chosen from a finite set of possibilities (such as from the set of directions defined by vectors connecting the vertices or the midpoints of edges or faces of a fixed polyhedron) as the closest approximation thereto. The most prevalent case is k=1, which produces a substantially uniform magnetic field, directed along the preferred φ=0 axis, within a portion of the central volume of the configuration. For instance, FIG. 2 shows magnetization vectors 14 selected according to the k=1 case within a region 11 surrounding a central volume 16.

In the present disclosure, the term modified Halbach magnet configuration (sometimes referred to as a magnet assembly or magnet array) means a configuration (or arrangement) of individual component magnets that comprises two or more subsets of magnets, at least one subset being configured in a Halbach cylinder magnet configuration and at least one other subset having another (non-Halbach cylinder) magnet configuration as discussed in this disclosure. In embodiments of the present disclosure, such modified Halbach magnet configurations provide a design context within which practical implementations of Halbach cylinders can be improved to provide magnetic fields having improved characteristics in applications. A subset of magnets may also be referred to as a plurality of magnets or a group of magnets. Examples of modified Halbach magnet configurations are described in PCT Application PCT/CA2020/051158 to Gallagher & Leskowitz, incorporated herein by reference in its entirety.

In the present disclosure, the term magnet rack means a collection of individual (component) magnets arranged in a holding structure so that their centers lie in a plane. By way of example, FIG. 5 depicts a portion of a magnet array (alternatively known as a magnet assembly or magnet configuration) which is generally designated 500. FIG. 5 shows a top view of one embodiment of a magnet rack 505 and individual component magnets 510. For clarity, the magnet array to which portion 500 belongs may include magnets in additional magnet racks not shown in FIG. 5.

In FIG. 5, the individual component magnets 510 are hexagonal prisms, each of which has a six-fold symmetry axis that is aligned out of the plane of the page. The individual hexagonal magnets 510 form a hexagonal-cylindrical arrangement surrounding a central cavity 520. In embodiments, the individual component magnets may be placed so their centers coincide with points in a lattice. In the present disclosure, the term lattice refers to a set of points, each of which is displaced from an origin by a sum of integer multiples of vectors chosen from a basis set {\hat{v}₁, \hat{v}₂, \hat{v}₃}.

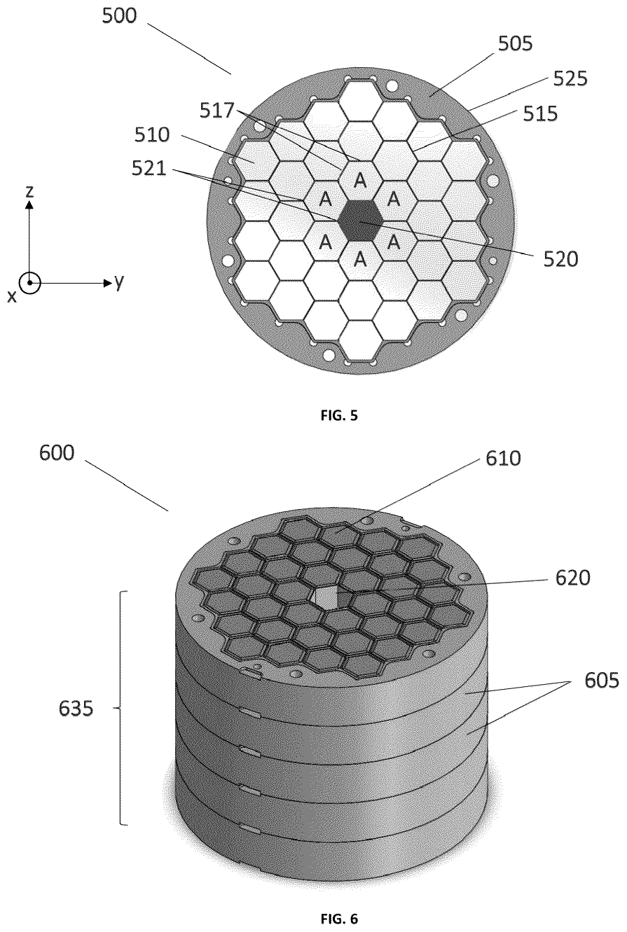

In the present disclosure, magnet rack stack means a collection of magnet racks that are stacked along an axis that is perpendicular to the said plane(s) containing the centers of the individual component magnets of the magnet racks. By way of example, FIG. 6 depicts a magnet array which is generally designated 600. FIG. 6 shows a perspective view of an embodiment of a rack stack 635, including five cylindrical magnet racks 605. An arrangement of component magnets 610 is visible in the top rack of the magnet rack stack surrounding a central cavity 620. In embodiments, a rack stack may contain 1, 2, 3, 4, 5, 6, 7, 8, 9, 10, or any number of magnet racks.

In embodiments of the present disclosure, the magnet arrangement in each rack may be the same or different from the other racks and may include the magnet arrangement of FIG. 5 and FIG. 6. As shown in these FIGS., thirty-six hexagonal prismatic magnets may be arranged in inner, middle, and outer rings of six, twelve and eighteen hexagonal prismatic magnets, respectively, and with the inner hexagonal prismatic magnets being closest to the central cavity, which in an NMR spectrometer may include a sample testing volume. Just as different numbers of magnet racks may be included in a magnet rack stack, although thirty-six magnets are illustrated in this example, other numbers, arrangements, and types of magnets and pole pieces may be used in a magnet configuration as described herein. In particular, in some embodiments, an inner ring of six component magnets, designated “A” in FIG. 5, may be modified in shape or in number in order to accommodate insertion of a removable magnet-insert assembly.

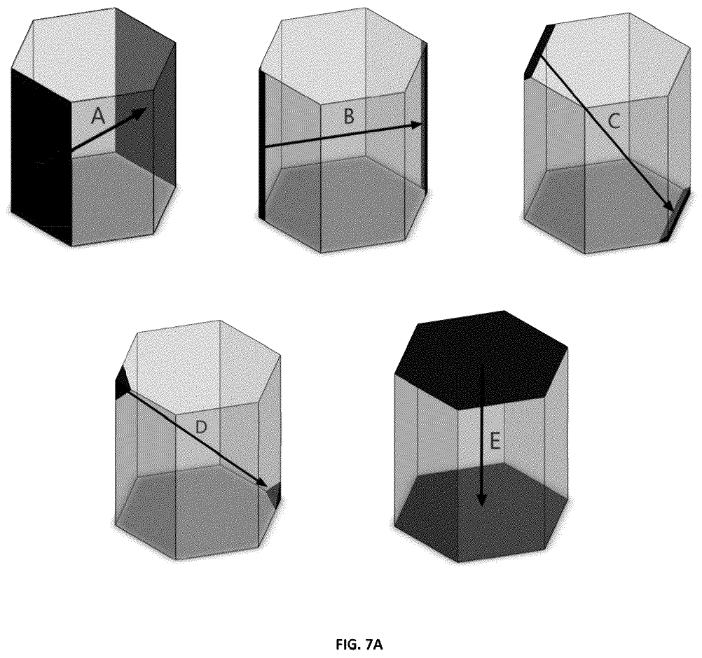

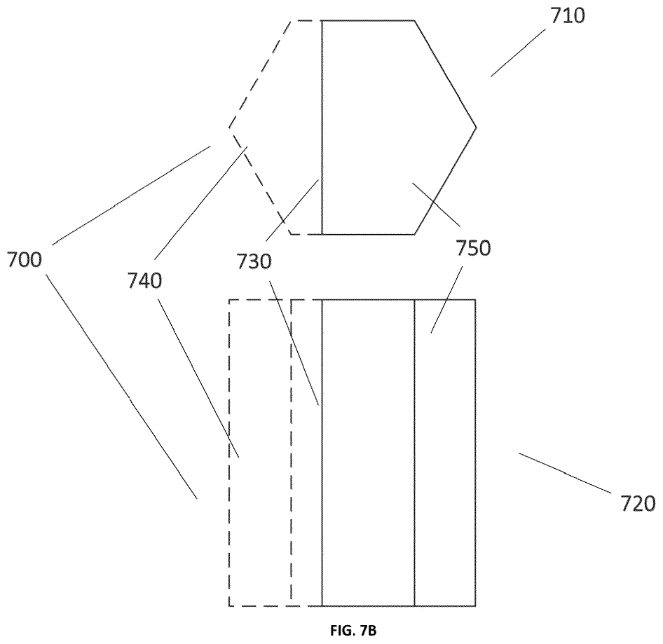

In the present disclosure, individual ones of the polyhedral magnets in a magnet configuration (also called an array, assembly, or arrangement) are selected from the group consisting of: a truncated cube; a rhombic dodecahedron; a Platonic solid; an Archimedean solid; a Johnson solid; a prism; a chamfered polyhedron; and a truncated polyhedron. A prism is understood to mean a polyhedron comprising two opposing congruent n-sided polygonal faces with corresponding sides of the polygonal faces joined by n rectangular faces. An example used in this disclosure is a hexagonal prism, wherein n equals 6. Examples of hexagonal prismatic component magnets, with a range of magnetization vectors, are exhibited in FIG. 7A. In the present disclosure, magnets A and B are said to be diametrically magnetized, with magnetization vectors perpendicular to the sixfold symmetry axis of the bodies' overall hexagonal prismatic shape. Magnets C and D are said to be obliquely magnetized, and magnet E is said to be axially magnetized.

In the present disclosure, a magnet having a magnetization vector lying in the plane (in-plane) defining a magnet rack (for example, in the yz plane shown in FIG. 5) is said to be diametrically magnetized. A magnet having a magnetization vector perpendicular to the plane of the magnet rack is said to be axially magnetized. A magnet having a magnetization vector that does not lie in the plane, but is not perpendicular to the plane, is said to be obliquely magnetized. A magnet that is either axially magnetized or obliquely magnetized is said to possess out-of-plane magnetization.

FIG. 7A shows examples of magnets that are in the shape of hexagonal prisms. In FIG. 7A, magnet A is a diametrically face-magnetized magnet, wherein the magnetization vector (indicated by an arrow) is normal to a rectangular side face of the magnet and perpendicular to the six-fold symmetry axis of the hexagonal face of the magnet. Magnet B is diametrically edge-magnetized, wherein the magnetization vector is perpendicular to the six-fold rotational symmetry axis of the hexagonal face of the magnet and extends from a long edge bounding a rectangular face of the magnet to the opposite edge across the body of the magnet. It will be readily appreciated that this vector is also parallel to certain opposing rectangular faces of the magnet B. FIG. 7A also shows a magnet E, which is axially magnetized, that is, magnetized along a vector that is coincident with the six-fold symmetry axis of the magnet.

Magnets C and D are examples of obliquely magnetized magnets. More precisely, magnet C is obliquely edge magnetized, wherein the magnetization vector extends from the midpoint of one edge bounding a hexagonal face of the magnet to the midpoint of the opposite edge bounding the opposite hexagonal face of the magnet and across the center of the magnet. It will be appreciated from FIG. 7A that the magnetization vector of magnet C is perpendicular to said edges and that the magnetization vector forms an acute angle with the six-fold symmetry axis of magnet C. Magnet D is obliquely vertex magnetized, having a magnetization vector that extends from one vertex, through the center of the magnet, to the opposite vertex. The magnetization vector of magnet D also forms an acute angle with the six-fold symmetry axis of magnet D.

An exemplary embodiment of a truncated polyhedron is the truncated hexagonal prism. FIG. 7B depicts a truncated hexagonal prism generally designated 700. Top view 710 and side view 720 show the hexagonal prismatic body 750. In order to truncate a polyhedron, one designates a planar surface 730 within the body and removes all of the material 740 on one side of the designated planar surface 730. The portion that remains is called a truncated polyhedron, which in the example shown in FIG. 7B is a truncated hexagonal prism. The magnetization vector of the body remains the same as before truncation and can in embodiments be any of the magnetizations depicted in FIG. 7A.

In the present disclosure, a magnetic field gradient is a characteristic of a magnetic field which has a spatial variation in its strength or direction. In many practical applications, and in particular in magnetic resonance applications, a magnet assembly that creates a strong, spatially homogeneous field is desired. In that case, a magnetic field \vec{B}(x, y, z) is well approximated by its projection along an axis, so that the magnetic field is expressed as a scalar value B_{z}, the component of the field along that axis.

In the present disclosure, a quadratic field gradient is a magnetic field gradient in which a component of the field varies in proportion to a second power of some spatial coordinate. For example, a magnetic field having a z component that is substantially of the form

$${B}_{z} ( x , y , z ) = {B}_{0} + a ( {x}^{2} - {y}^{2} ) + …$$

possesses a quadratic field gradient due to its spatial dependence on the second power of the coordinates x and y. Note that, in the present disclosure, “bilinear” gradients such as those exhibited by a field of the form

$${B}_{z} ( x , y , z ) = {B}_{0} + b ( xy ) + …$$

are formally quadratic according to this definition since the function xy=(u²−v²) when expressed in the linearly related coordinates

$$u = \frac{1}{2} ( x + y ) and v = \frac{1}{2} ( x - y ) .$$

In the present disclosure the term magnetic resonance or MR means resonant reorientation of magnetic moments of a sample in a magnetic field or fields, and includes nuclear magnetic resonance (NMR), electron spin resonance (ESR), magnetic resonance imaging (MRI) and ferromagnetic resonance (FMR). As the present disclosure pertains to methods and apparatuses for rendering general static magnetic fields more uniform, in embodiments the disclosure is also applicable in ion cyclotron resonance (ICR) or in trapped-ion or particle-beam technology generally. For simplicity of explanation, the term magnetic resonance or MR as used herein will be understood to include all these alternative applications. In particular applications and embodiments, the apparatuses and methods disclosed are applied to NMR and in embodiments they are applied to NMR spectrometers or to NMR imagers. Materials that display magnetic resonance when exposed to a magnetic field are referred to as magnetically resonant or MR active nuclides or materials.

In the present disclosure the terms primary field, main field, primary magnetic field and main magnetic field mean the magnetic field generated by a magnet array. In one series of embodiments a field strength in the range of 1.0 to 3.0 Tesla is achieved. However, in alternative embodiments, the field strength may be below 1.0 Tesla or above 3.0 Tesla. The field strength will depend on the number of magnet racks, the strength of the individual component magnets, the presence or absence and types of pole pieces, construction materials used, and other variables.

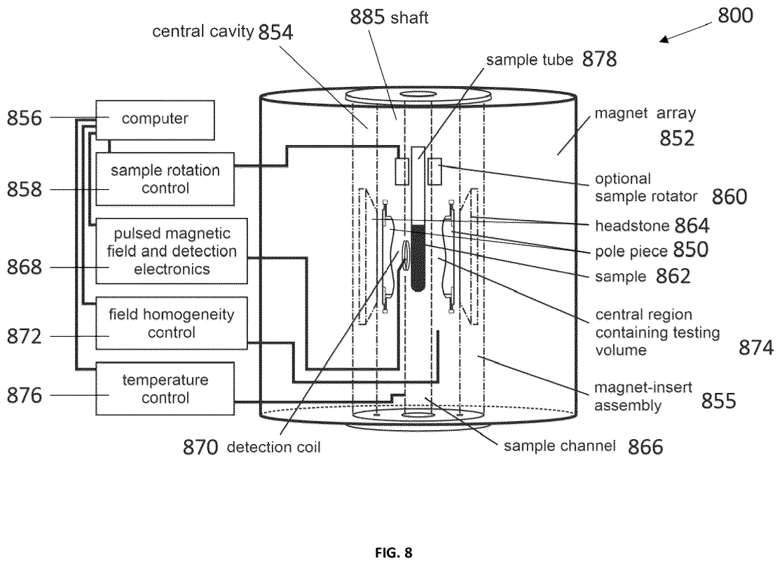

In embodiments of this disclosure, the magnet array may be comprised in a magnetic resonance apparatus (device). For example, FIG. 8 is an exemplary block diagram of a magnetic resonance device 800 in accordance with an embodiment of the disclosure. The magnetic resonance device 800 includes a magnet array 852 within which a magnet-insert assembly 855 is installed. For clarity of illustration, not all components of the magnet-insert assembly 855 are shown; in FIG. 8, two headstones 864 of the magnet-insert assembly are illustrated and positioned within a central cavity (or central bore) 854 of the magnet array 852. The magnet-insert assembly 855 defines a shaft 885 therein. Additional aspects of the magnet-insert assembly are described in this disclosure and in other figures herein.

Two pole pieces 850 are shown schematically in FIG. 8 positioned in the magnet array 852, within the shaft 885 of the magnet-insert assembly 855. In embodiments, the pole pieces 850 are supported (assembled with) a positioner to yield a central cavity assembly that is positioned within the shaft 885; however, the positioner and central cavity assembly are excluded in FIG. 8 for clarity of illustration.

The device 800 further comprises a computer 856 operably connected to a sample rotation control module 858 for controlling rotation of an optional sample rotator 860 used for rotating a sample 862 in a sample tube 878 within a sample channel 866 provided in the magnet array 852.

The computer 856 may also be operably connected to a pulsed magnetic field control and signal detection electronics module 868 used for controlling a detection coil 870 and receiving a signal therefrom. The device 800 may also include a field homogeneity control module 872 for controlling the magnetic field in a centrally located testing volume 874. A temperature control module 876 may also be provided for controlling the temperature inside the channel 866.

### Creating SPACE IN THE CENTRAL CAVITY

Returning to the magnet rack 505 of FIG. 5, the magnets 510 are illustrated as magnetized according to a Halbach cylinder configuration. The magnet rack 505 further comprises a cell framework 515 and a framework housing 525. The cell framework 515 is to be considered a nominal framework in this disclosure against which other frameworks can be compared. The cell framework may be made of a suitable weakly magnetic or nonmagnetic material, for example a metal such as aluminum or titanium, a high-performance plastic such as Delrin or ABS, or a ceramic or glassy material, or any combination thereof.

An example of a function of the cell framework is to guide the placement of individual component magnets in the magnet rack during assembly of the rack. Another example of a function of the framework is to provide separation between some or all magnets in the rack. In other words, the cell framework defines a number of cells, each cell for receiving one or more individual component magnets into the magnet rack.

In embodiments, the geometric center of each cell in a framework is a point that substantially coincides with a point in a lattice. In the example of FIG. 5 the lattice is a two-dimensional hexagonal lattice. It will be understood that when racks are stacked as shown in FIG. 6, the resulting lattice is a three-dimensional hexagonal Bravais lattice.

As illustrated in FIG. 5, the cell framework 515 defines multiple cells, the innermost six of which, surrounding the central cavity 520, are labeled A for convenience. Additional magnets are positioned farther away from the central cavity. Although not illustrated in FIG. 5, the size, composition, and magnetization direction of the individual hexagonal magnets may vary, e.g., some magnets in the array may be larger than other magnets in the array. In this example, the cell framework 515 can accept up to thirty-six magnets positioned around the central cavity 520. However, in other embodiments, variations in magnet numbers are possible and one, two, or more than two types and/or sizes of magnets may be incorporated into the Halbach-based array.

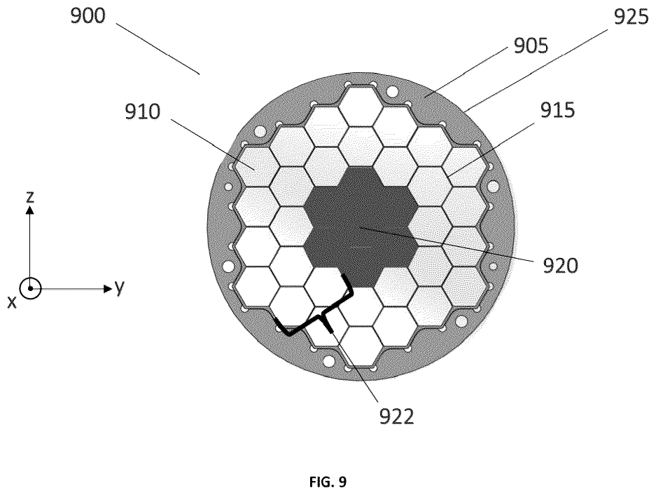

In use, a sample, such as a chemical sample, will generally be positioned in a defined sample volume, sample space, or testing volume at or close to the center of the central cavity 520. The cell framework 515 further includes framework sections 517 which are connected to one another through framework vertices 521. (Not all framework sections and vertices are explicitly labeled in the figure.) A Cartesian coordinate axis system is shown in both FIG. 5 and FIG. 9 (described below), with the x-axis being directed out of the plane of the page.

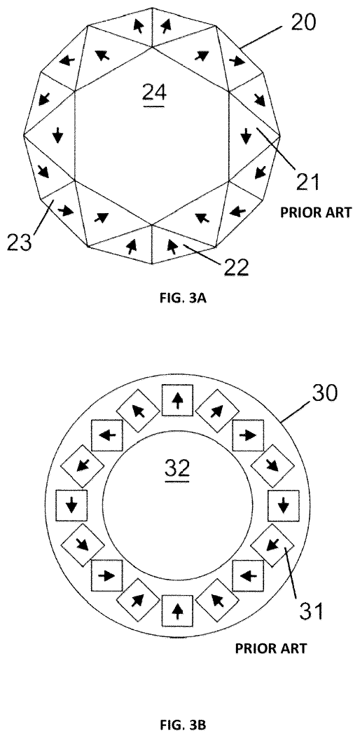

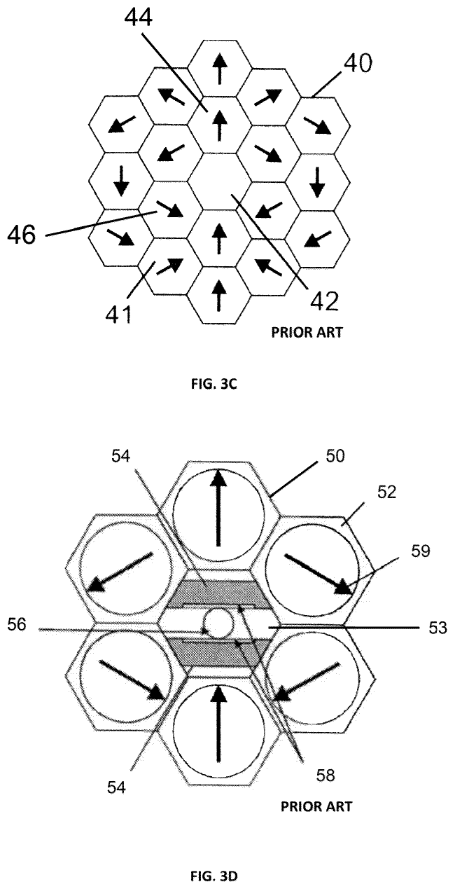

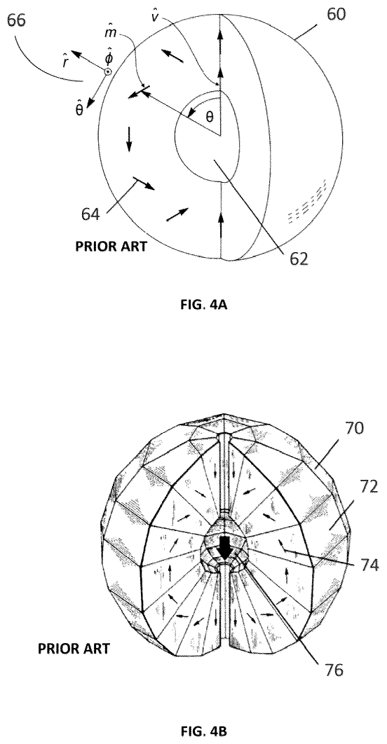

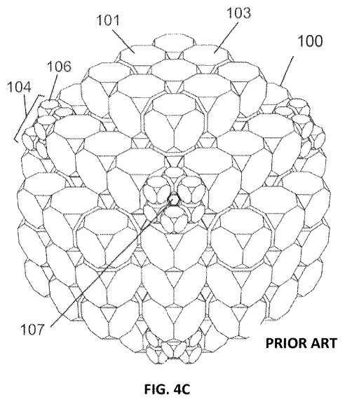

One way to increase the strength of a magnetic field in a magnet array is to use pole pieces, which can acquire a magnetic polarization when placed in a magnetic field. This polarization can increase the strength of the magnetic field in the region of space near the pole piece to a value that is larger than it would be in the absence of the pole piece. Sometimes in applications it is desirable to use pole pieces in pairs rather than individually. As described above, FIG. 3D shows a known example configuration of pole pieces 54 within a hexagonal cavity defined by a set of six magnets 52, each of which is in the shape of a hexagonal prism.

In this disclosure, a preferred way to increase the strength of the magnetic field in a magnet array is to use pole pieces in other positions in the magnet array that are close to the sample volume and chosen to enhance the strength of the field. We emphasize here that the sample volume is generally inside the central cavity, that is, the central cavity is a larger region than the sample volume and may contain other features, devices, or materials in addition to the sample volume. A sample volume is a region of space within the central cavity that can receive a sample (e.g., such as a chemical sample) under study. A goal of this disclosure is to provide apparatuses and methodologies for increasing the magnetic field strength for applications in a manner that permits relaxation of certain constraints limiting the use of magnet arrays based on Halbach cylinders. One of those limiting constraints is a small size of the central cavity. In this disclosure, a judicious choice of the shape and positioning of pole pieces may allow for increasing the size of the central cavity to create more space for thermal (temperature) regulation and shimming technology to improve the temperature stability of the magnet configuration, the homogeneity of the magnetic field, and the overall performance of the magnet array.

Illustrative of another embodiment of the present disclosure, FIG. 9 depicts a magnet array which is generally designated 900. FIG. 9 shows a top view of a magnet rack 905 and individual component magnets 910. FIG. 9 differs from FIG. 5 in that the central cavity 920 is larger in FIG. 9 than the central cavity 520 shown in FIG. 5.

The central cavity 920 in FIG. 9 includes the space where a first ring of six hexagonal prismatic magnets (labeled A) would have been positioned around the smaller central cavity 520 as shown in FIG. 5. The outer rings 922 are still present in the magnet array 900, with the component magnets held in place by cell framework 915 and framework housing 925. The larger cavity 920, like the smaller cavity 520, is convenient for use with a lattice-based implementation of a Halbach cylinder, and, in particular, with use of a repeated unit—the diametrically magnetized hexagonal prism—which can be fabricated in bulk quantities for reduced cost, convenience in assembly, and tight manufacturing tolerance. However, the larger central cavity 920 has advantages over a smaller cavity. These advantages include more space to incorporate improved thermal isolation measures relative to prior art designs, and more space with which to position larger pole piece assemblies. These advantages are purchased at the cost of somewhat lower field produced by a magnet array that is on average further away from an enclosed sample volume. It is a main purpose of the present disclosure, and in particular to the magnet-insert assembly described below, to address this tradeoff.

In the non-limiting embodiment of a rack stack illustrated in FIG. 6, the magnet racks are 1.5″ in height, as are the hexagonal prismatic magnets within the racks (1.5″ along the six-fold symmetry axis of the hexagonal prism). The cells in the cell framework are 1.25″ across (from the midpoint of one edge to the midpoint of the opposing edge across a hexagonal face), and the walls making up the framework itself are 0.030″ thick. In alternative embodiments, the magnet dimensions and cell framework dimensions may be larger or smaller depending on the application and the desired magnetic field strength.

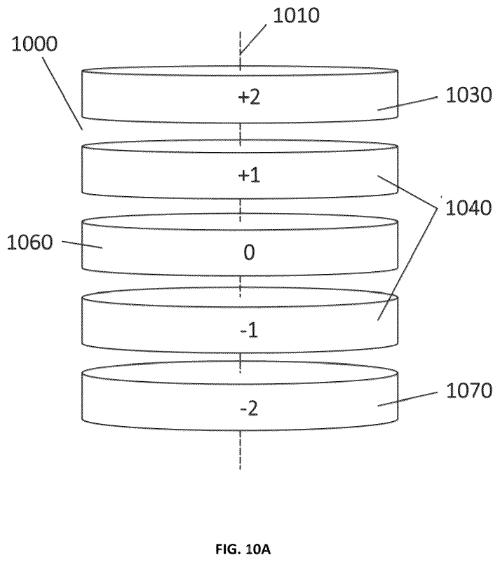

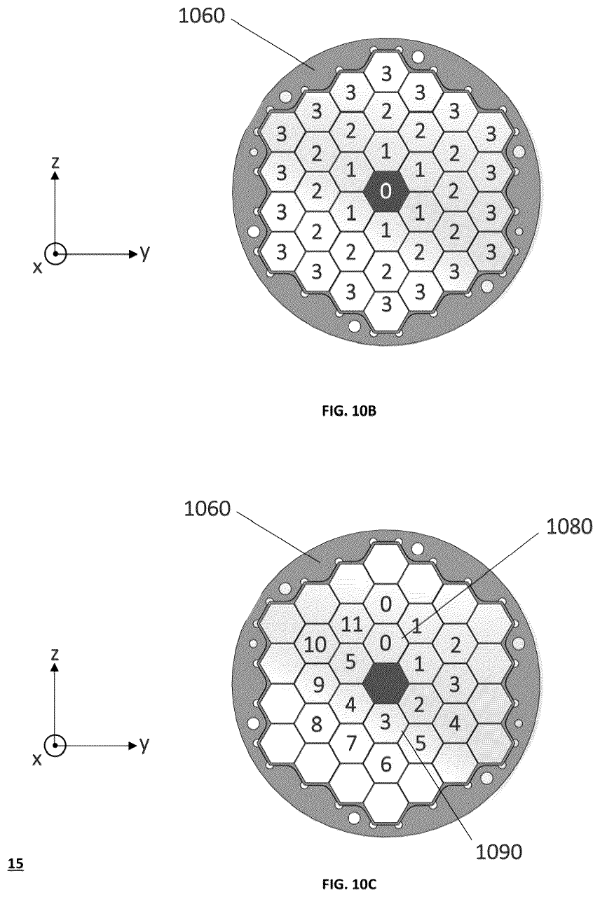

FIG. 10A shows a magnet rack stack 1000 of five cylindrical racks in perspective view. The racks are stacked so that their centers align along a central axis 1010. The rack stack comprises a first (top) rack 1030, two intermediate racks 1040 (second and fourth in order from the top), a third (central or center) rack 1060, and a fifth (bottom) rack 1070.

Such a plurality of stacked racks, with one of said racks designated as the center rack, may be configured to receive magnets such that the center of each magnet is positioned in a hexagonal Bravais lattice configuration around a central cavity that extends longitudinally from the top rack to the bottom rack through the center of each rack. Each of the lattice configuration sites may be specified by three integers: a rack coordinate, a radial ring coordinate, and an azimuthal coordinate.

Rack coordinates are indicated by the numbers +2, +1, 0, −1 or −2 in FIG. 10A. In embodiments where additional magnet racks are included such that the total number of racks equals an odd number, the rack coordinates may continue to increase (i.e., +3, +4 . . . for racks at the top of the magnet rack stack) and decrease (i.e., −3, −4 . . . for racks at the bottom of the magnet rack stack). If the total number of magnet racks in a rack stack equals an even number, then the “0” rack coordinate may be excluded. For instance, a magnet rack with four racks would have rack coordinates +3/2+1/2, −1/2 and −3/2. A magnet rack with six racks would have rack coordinates +5/2, +3/2, +1/2, −1/2, −3/2 and −5/2, and so on.

A radial ring coordinate may be chosen such that a lattice site designated as the center of the magnet array in a given magnet rack is assigned a radial ring coordinate of zero, said radial ring coordinate further selected such that each hexagonal ring of lattice sites in the magnet rack is assigned a coordinate incremented by one relative to its inner neighbor.

Radial ring coordinates are indicated by the numbers 0, 1, 2 or 3 in FIG. 10B, which shows a top view of the central rack 1060 of FIG. 10A. A preferred sample volume will be situated at or near the central location at radial ring coordinate 0 and rack coordinate 0 and may extend for a distance that is small compared to a rack or ring coordinate spacing or equal to or larger than a rack or ring coordinate spacing as needed for an application. If fewer or more rings of magnets are present in a magnet rack, then the rings would be numbered accordingly in the same manner as shown in FIG. 10B.

Azimuthal coordinates are indicated by the numbers 0, 1, 2, . . . as shown in FIG. 10C. It will be appreciated that, as the numbers of magnets contained in radial rings 1, 2, 3, . . . , n are equal to 6, 12, 18, . . . , 6n, an appropriate azimuthal integer coordinate will take on the values from 0 to 6n−1 in a ring with radial ring coordinate equal to n. For example, in radial ring 1, azimuthal coordinates run as shown from 0 to 5, and in radial ring 2, azimuthal coordinates run as shown from 0 to 11. A particularly convenient choice for the component magnet labeled with azimuthal coordinate 0, for example magnet 1080, is the component magnet displaced from the central axis along the primary field direction of the Halbach cylinder as a whole, that is along the z axis in FIG. 10C.

The cell framework of each rack in FIG. 10A has a central cell at radial ring coordinate 0, and for each such cell the azimuthal coordinate is not and need not be defined. The “north” and “south” magnetic pole directions coincide with framework cells with azimuthal coordinates 0 and n/2 in radial ring n. For example, as shown in FIG. 10C, the cells labelled “0” and “3” in ring 1 correspond to the “north” and “south” directions of the Halbach magnet as a whole. Resultant from the preceding description of rack and cell nomenclature, each magnet or framework cell is assigned a unique trio of rack, radial-ring, and azimuthal coordinates. For example, in FIG. 10C, magnet 1080 has rack, ring, and azimuthal coordinates (0, 1, 0), and magnet 1090 has coordinates (0, 1, 3).

Returning to FIG. 9, the rack coordinates, radial ring coordinates, and azimuthal coordinates continue to apply; however, the central cavity 920 is understood to encompass not only a central, unoccupied hexagonal prismatic bore within a magnet rack (radial ring coordinate position “0”), but in addition is understood to encompass the space denoted by the ring assigned radial ring coordinate positions “1” in FIG. 10B.

By opening up the central cavity from the size shown in FIG. 5 to the larger size shown in FIG. 9, opportunities are created for increasing the magnetic field produced by a magnet array, managing the temperature of the air and contents within the central cavity, and improving the homogeneity of the magnetic field. All of these opportunities lead to improved performance of a magnetic resonance device incorporating the magnet array. In particular, an increase in magnetic field relative to prior art Halbach cylinders can be achieved by inserting a pole piece, such as one shaped (by example and without limitation) as a hexagonal prism, of a suitable soft (permeable) magnetic material at azimuthal positions 0 and 3 in radial ring 1 (see FIG. 10C). This is possible because suitable soft magnetic materials, such as some grades of steel, and alloys such as Hiperco, bear saturation magnetizations that are substantially higher than remanent magnetizations of available hard magnetic materials, such as neodymium-iron-boron.

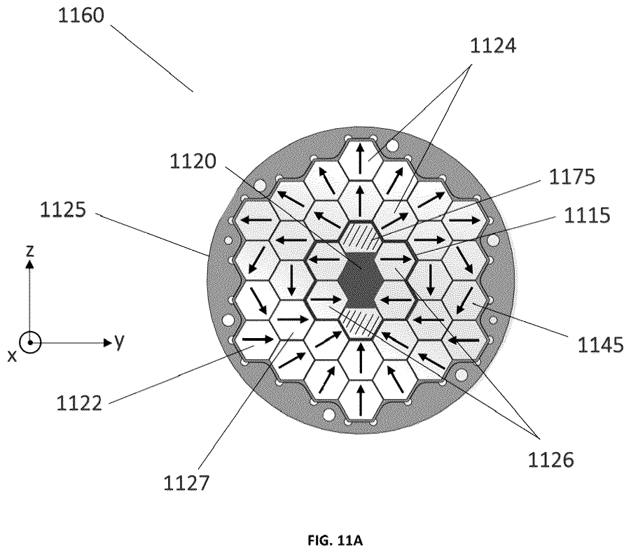

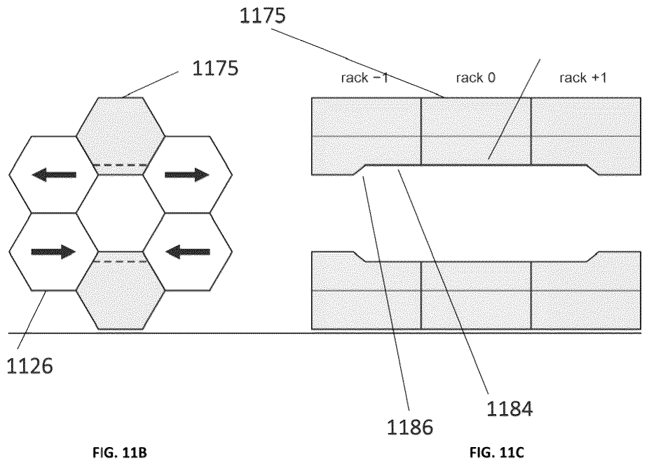

The space provided by a larger central cavity, such as central cavity 920 shown in FIG. 9, can be occupied by materials that support the opportunities for increased field strength, improved homogeneity, and improved thermal isolation. In one embodiment of the present disclosure, a magnet rack may have a configuration of magnets and pole pieces as shown in FIG. 11A.

FIG. 11A shows a central rack 1160 in top view. Hexagonal prismatic component magnets are positioned within a framework housing 1125 and cell framework 1115, with magnetization vectors indicated by arrows 1122. According to this disclosure, some of the magnets, e.g., 1124, belong to a subset of magnets that are strictly magnetized along a vector prescribed by a Halbach cylinder configuration. Some of the magnets, e.g., 1145, belong to a subset of magnets that are magnetized along a vector that is a closest approximation to a Halbach cylinder configuration given a constraint that the magnetization be chosen from the finite set of possibilities shown for a hexagonal prism in FIG. 7.

Four magnets 1126, each with a radial ring coordinate of 1 and therefore within the enlarged central cavity 1120 of the present disclosure, are diametrically edge-magnetized and do not conform to a Halbach cylinder configuration. A last subset of magnets, e.g., 1127 exhibit magnetization vectors that do not strictly conform to a Halbach cylinder configuration, but, rather, are reoriented in order to reduce coercive stress on the component magnets at those locations at the cost of a modest decrease in field strength in the sample volume. This type of magnet (1127) and positioning is also discussed in PCT Application PCT/CA2020/051158 to Gallagher & Leskowitz.

It should be noted that not every magnet (1124, 1145, 1126, 1127, etc.) that is described with respect to a given figure is explicitly indicated in the figure. For example, of four magnets 1126 in FIG. 11A, just two of four are indicated by the reference number 1126.

Also illustrated in FIG. 11A are two hashed areas 1175 which represent positions where magnetically permeable material is used in the magnet rack. For example, steel or hiperco alloy may be used in these locations 1175. It should be noted that although there are two regions 1175 where magnetically permeable material is placed in FIG. 11A, just one is explicitly indicated. As well, FIG. 11A illustrates that a central space 1120 has been expanded compared to 520 shown in FIG. 5, for example, because each steel piece is not a ‘perfect’ hexagonal prism; rather the face of each steel piece 1175 that is proximal to the central space 1120 is truncated to make more room in the central space 1120.

Further, portions of the cell framework (see FIG. 5) that might otherwise be proximal to the central space 1120 have been removed (in other words, are not present in this embodiment in FIG. 11A). The cell framework 1115 closest to the central space 1120 is shown with a thicker line; for the purposes of this figure, the thicker line is for emphasis and does not necessarily represent a physically thicker cell framework.

Removing, for example, approximately 0.150″ of material off the face of each magnetically permeable piece proximal to the central space 1120 may reduce the effect of some (in particular, quadratic) magnetic field gradients that may otherwise be produced. The exact size and surface shape of the magnetically permeable pieces can be optimized using field measurements or magnetostatic simulations. A further advantage of removing both the magnetic material and the (for example, aluminum) corresponding cell framework is a reduced effective thermal conductivity in that region.

Suitable materials for the magnetically permeable pieces are steel, soft iron, hiperco alloys, or pieces made of these materials in bulk and coated with other metals, such as gold or nickel, or with epoxy or other suitable polymer materials to improve resistance to corrosion.

In an embodiment, in a magnet rack stack of five magnet racks, magnetically permeable pieces may be used in six positions: two opposing positions having a radial ring coordinate of “1” in each of racks −1, 0, and +1 (as shown for rack “0” in FIG. 11A) and having azimuthal coordinates 0 and 3. These positions are compatible with the Halbach magnet configuration as a whole because the predominant magnetic field present within these lattice sites is along the direction which magnetizes the permeable magnetic material favorably for enhancing the magnetic field produced by the other component magnets. Therefore, inserting permeable pieces in these six positions increases the strength of the magnetic field. A further benefit is that the use of these pole pieces allows for a larger central space. Because the permeable pieces generally have a low temperature coefficient (typically ˜20 ppm per degree Celsius) compared to that of NdFeB rare-earth permanent magnets (˜1100 ppm per degree Celsius), using the permeable pieces may allow for improved thermal control when the magnet rack stack is used as part of an analytical device such as an NMR spectrometer for chemical analysis. In other words, such a configuration of magnets and magnetically permeable pieces may have improved stability when exposed to temperature changes (for example, temperature changes in the central space) and may provide a homogeneous region around a sample positioned in the central space for analysis by magnetic resonance techniques, especially when used in combination with additional pole pieces and electronic shimming measures inserted into the central cavity, as described below.

In embodiments, the permeable pieces may not be the same size in racks −1, 0 and +1. FIG. 11B shows a portion (just radial rings 0 and 1) of the top view of rack 0 of FIG. 11A. FIG. 11C shows a side view of the central cavity 1120 of FIG. 11A spanning three racks −1, 0 and +1 in a rack stack. As in FIG. 11A, FIG. 11B shows four diametrically edge-magnetized component magnets 1126 and two magnetically permeable pieces 1175. For clarity, the component magnets 1126 are not shown in the side view of FIG. 11C.

The portion of the magnetically permeable pieces 1175 that are in rack 0 are smaller in the dimension shown by an amount roughly equal to about 0.150″ (12%) of the total thickness 1.250″ of the cell site in the framework in this example, but the reduction in size can range from about 0% to about 50% or more in applications. Also shown in the side view of FIG. 11C is a cutaway region 1184 extending into rack −1 and, by symmetry, rack +1, and an angled portion 1186 at the end of the cutaway region. In embodiments, the cutaway region 1184 may extend for variable length within the outer racks −1 and +1 and in other embodiments may extend between 0% and 100% of the length of the permeable piece element within racks −1 and +1. The angled portion can exhibit variable angles in embodiments.

As a whole, the cutaway and angled features provide for the magnet array a larger central space within which thermal control measures such as insulation, heating elements, Dewar walls, circulated heat-transfer fluids, or the like can be inserted as needed for more precise temperature control of the component magnets or thermal isolation of the component magnets from a sample that may be at a temperature that is different from that of the component magnets.

### Magnet-INSERT ASSEMBLY—MAGNET ARRAY

In the present disclosure, the term “magnet structures” includes magnet arrays (sometimes referred to as magnet assemblies or magnet configurations), magnet racks, magnet rack stacks, magnetic resonance devices (sometimes referred to as spectrometers or scientific/laboratory instruments), and ancillary magnetic apparatuses such as magnetic assemblies or sub-assemblies that are insertable and/or removable from a central cavity in a magnet array, magnet rack, magnet rack stack, or magnetic resonance device.

The present application discloses a removable magnet-insert assembly, configured for insertion into a magnet array. The removable magnet-insert assembly comprises certain unique, novel features that improve the magnetic field strength, uniformity, and thermal stability of the magnet array into which it is inserted. Accordingly, use of the magnet-insert assembly may improve the reliability and suitability of the magnet array in magnetic resonance applications.

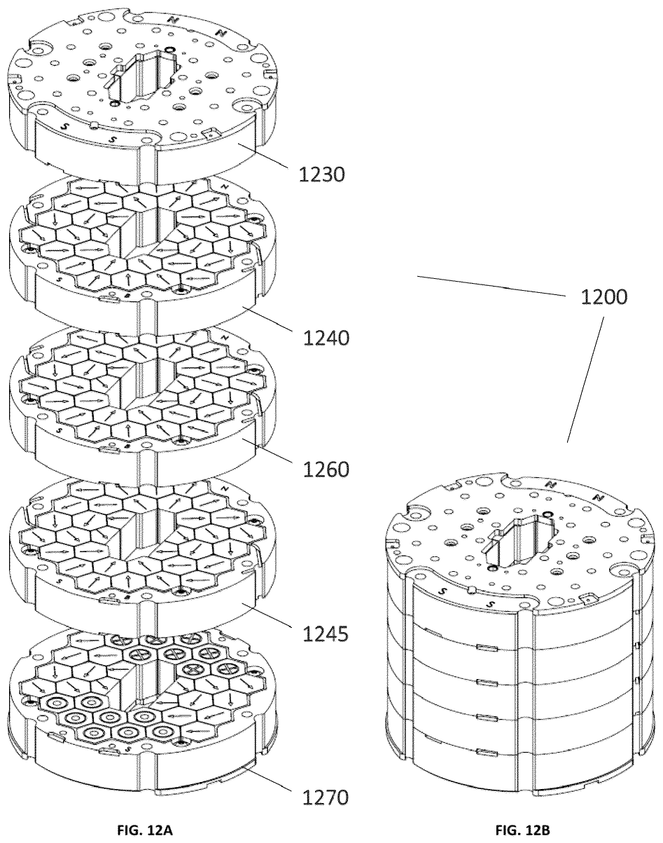

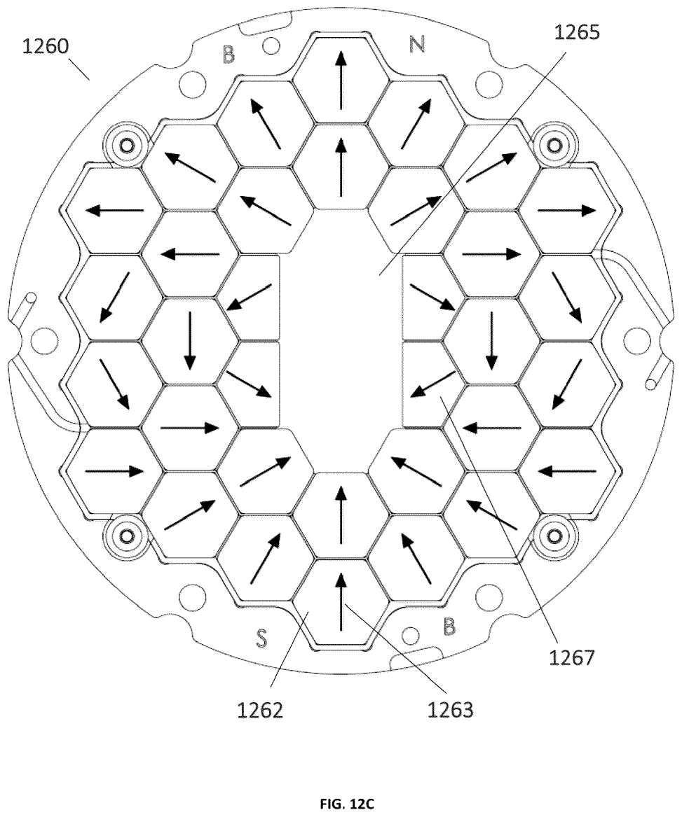

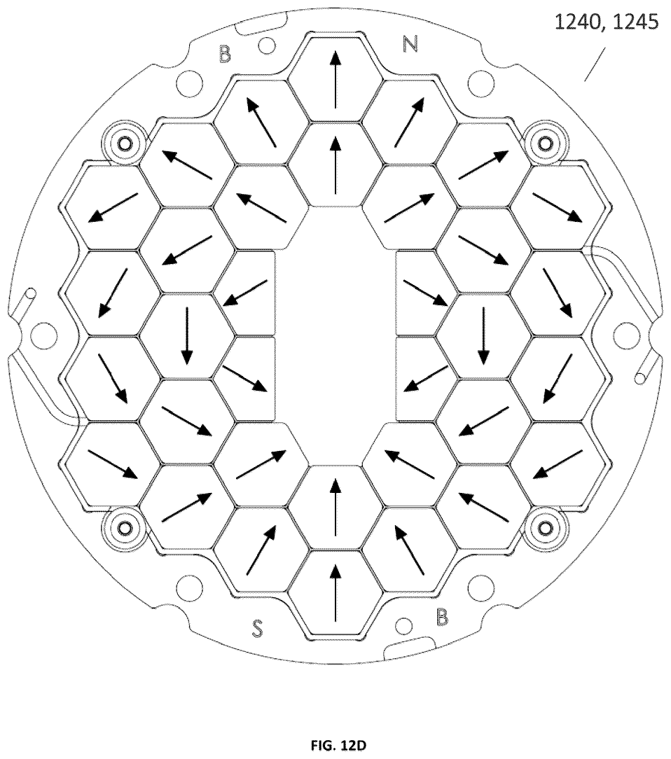

Before fully describing the disclosed magnet-insert assembly, we first summarize the foregoing descriptions of magnet arrays into an exemplary embodiment of a magnet array suitable for use with the disclosed magnet-insert assembly. The summary and its depiction in figures, specifically FIGS. 12A-12E, will serve to clarify the claimed features of the magnet-insert assembly.

The present application discloses a magnet array generally designated 1200 comprising a plurality of magnet racks 1230, 1240, 1245, 1260, and 1270, one of said magnet racks 1260 designated as the center rack. In the embodiment shown in exploded view in FIG. 12A, rack 1230 is designated as a top rack, racks 1240 and 1245 are designated as intermediate racks, and rack 1270 is designated as a bottom rack. The magnet array 1200 is shown assembled in FIG. 12B. FIGS. 12C, 12D, and 12E show individual racks in top view. FIG. 12C shows central rack 1260, with individual component magnets 1262 shown magnetized according to magnetization vectors 1263. The magnet array comprises component magnets, the centers of each of which are located at points in a hexagonal Bravais lattice configuration around a central cavity 1265. Each of the lattice configuration sites may be specified by three integers: a rack coordinate, a radial ring coordinate, and an azimuthal coordinate. The radial ring coordinate may be chosen so that a site designated as the center of the magnet array is assigned a radial ring coordinate of zero. Said radial ring coordinate is specified such that each hexagonal ring of sites in the magnet rack is assigned a radial ring coordinate incremented by one relative to its inner neighbor. FIGS. 10A-C depict an example assignment of rack, radial ring, and azimuthal coordinates to component magnet sites in a hexagonal Bravais lattice configuration.

FIG. 12D shows the magnetization configurations of intermediate racks 1240 and 1245, and FIG. 12E shows the magnetization configurations of bottom rack 1270. The magnetization configuration of top rack 1230 is not shown explicitly but can be obtained by reversing the polarity of axial magnets 1272 and 1274 in the configuration of FIG. 12E.

The magnet array 1200 comprises a first plurality of hexagonal prismatic magnets, each occupying a lattice site such that the magnetization vectors of said hexagonal prismatic magnets are arranged in a cylindrical Halbach configuration having a designated predominant magnet field direction.

Said central cavity 1265 comprises lattice sites assigned radial ring coordinates zero and one in at least one magnet rack of a rack stack of the magnet array 1200. Within some of these lattice sites are placed component magnets 1267 in the shape of truncated hexagonal prisms. Note that, in this disclosure, when a truncated magnet is placed “in” or “at” a lattice site, it means that the magnet is placed so that the center of the corresponding non-truncated version of the magnet shape would be located coincident with the point on the defining Bravais lattice.

Within the magnet array 1200, the rack coordinate may be selected so that sites in each rack are assigned a rack coordinate incremented by one relative to the corresponding site in a neighboring rack, and further specified so that a rack coordinate of zero is assigned to magnets in said center rack 1260.

The magnet array 1200 may further comprise a second plurality of magnets located in designated sites within designated magnet racks, the second plurality of magnets each having a magnetization vector such that the second plurality of magnets is arranged in a non-Halbach configuration. Axial magnets 1272 and 1274 in FIG. 12E are examples of component magnets having magnetizations in a non-Halbach configuration. The magnetization vectors of said second plurality of magnets may be aligned along a vector normal to said magnet racks or aligned obliquely as depicted in FIG. 7A.

The magnet array 1200 may further comprise magnets located substantially at lattice sites in the central cavity with a radial ring coordinate equal to one. Said magnets within the central cavity defined by radial ring 1 are in the shape of truncated hexagonal prisms. The new face produced by the truncation of these magnets 1267 faces inwards into the central cavity 1265 and helps to define the shape of the central cavity into which the magnet-insert assembly (shown in subsequent figures) is inserted and positioned.

### Magnet-Insert Assembly

The present application discloses a removable magnet-insert assembly, configured for holding and aligning a removable central cavity assembly, and further configured for insertion into a magnet array. The magnet-insert assembly comprises:
one or more headstones;
one or more permanent magnets; and
a substructure adapted to receive and secure the headstone(s), the permanent magnet(s), and the removable central cavity assembly and to position these in the magnet array.

In this disclosure, a central cavity assembly is a device which comprises pole pieces or pole-piece assemblies and a pole piece positioner. It may also in embodiments comprise means for aligning, orienting, or supporting the pole pieces or pole-piece assemblies or mounting features for holding and aligning a sample probe, electronic components, shim panels, thermal insulation, or other components or devices that may be useful to have within the central cavity in applications.

In embodiments of this disclosure, a headstone is a body or multi-part structure which is wholly or in part made of a magnetically permeable material and, accordingly, acquires a magnetic polarization when inserted into a magnet array. In exemplary embodiments to follow, the removable magnet-insert assembly comprises two tapered headstones.

In embodiments, each tapered headstone comprises a front face, a rear face, and a predominant magnetization axis near said front face which is substantially perpendicular to both the front face and the rear face, and the pair of headstones is disposed so that their respective front faces are substantially parallel and lie facing one another across a shaft defined by the magnet-insert assembly. In this disclosure, the portion of the shaft between the two headstones is referred to as a gap or space within the shaft. In embodiments, each tapered headstone further comprises an insertion axis perpendicular to the said magnetization axis. As will be observed in the exemplary embodiments to follow and in the associated figures, a total of four permanent magnets may be positioned so that a pair of permanent magnets are disposed one on each side of each tapered headstone along the insertion axis.

In some of the embodiments and examples described below, tablets are positioned on the faces of headstones, in recesses (depressions) provided in the front faces of headstones, or within recesses or chambers defined within multi-part headstone assemblies. In this disclosure, a tablet is a shaped piece of metal or other material which may be magnetically permeable and may accordingly acquire a magnetic polarization when inserted into a magnet array. The magnetic polarization of such a tablet may be used to modify (shim) the overall magnetic field configuration within the gap (space) between headstone front faces. The presence, absence, number, shape, composition, permeability, and configuration of the tablets may thus provide a magnetic-field shimming capability for a user. In the exemplary embodiments described below, eight tablets are used within a magnet-insert assembly, but more or fewer than eight tablets may be used in applications, and all such modifications are considered as possible variants comprised in the scope of the disclosure.

In embodiments, the magnet-insert assembly is configured for insertion into a magnet array comprising component magnets arranged in a Halbach-cylinder configuration. In alternative embodiments, said magnet array comprises a plurality of magnets arranged in a Halbach-cylinder configuration and a second plurality of component magnets arranged in a non-Halbach configuration.

In exemplary embodiments, a magnet array may comprise component magnets that are polyhedral, and the magnet-insert assembly may be shaped to conform to a central cavity defined by the arrangement of the innermost polyhedra.

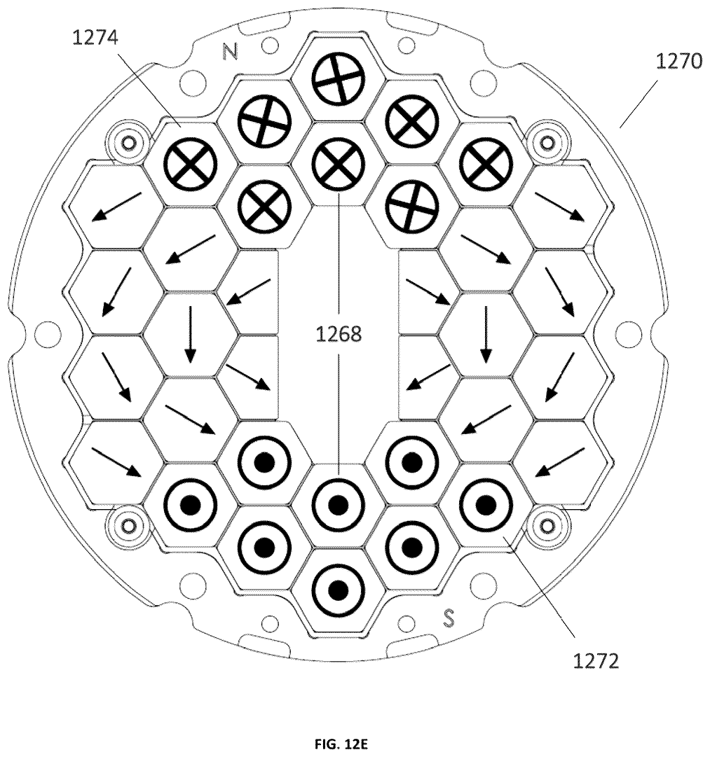

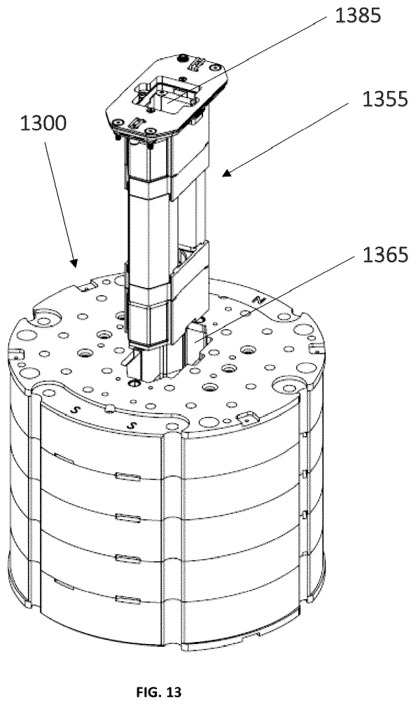

Illustrated in FIG. 13 is a perspective view of a magnet array 1300 and a removable magnet-insert assembly 1355. The magnet-insert assembly in the example shown in FIG. 13 defines an opening (a shaft) 1385 within the magnet-insert assembly, the shaft 1385 being substantially aligned along a longitudinal axis of the magnet-insert assembly 1355. The magnet-insert assembly 1355 is shown positioned above a central cavity 1365 of the magnet array 1300 prior to insertion (or after removal) of the magnet-insert assembly 1355 into (or out of) the central cavity 1365 of the magnet array 1300. The magnet array 1300 and magnet-insert assembly 1355 cooperate to produce a resultant structure that may be used in or manufactured into a magnetic resonance device for sample analysis such as the device 800 illustrated in FIG. 8.

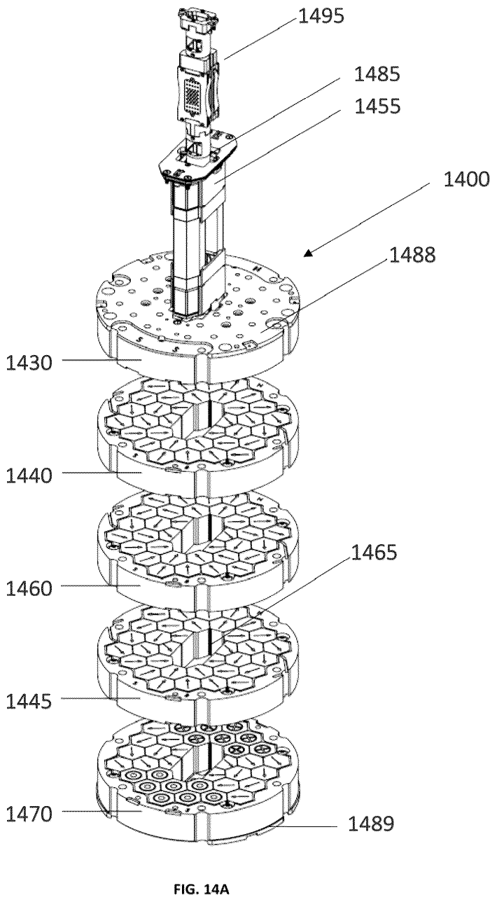

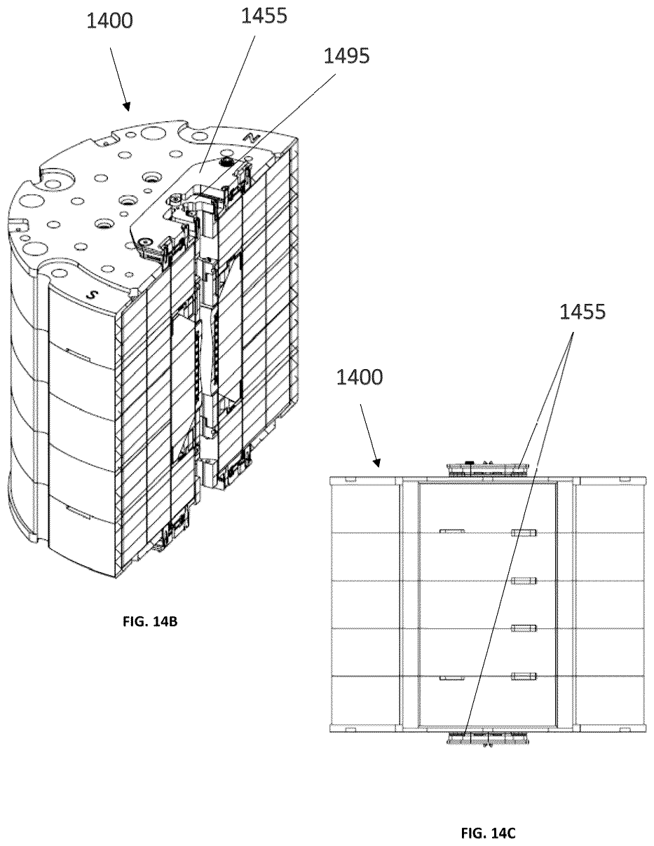

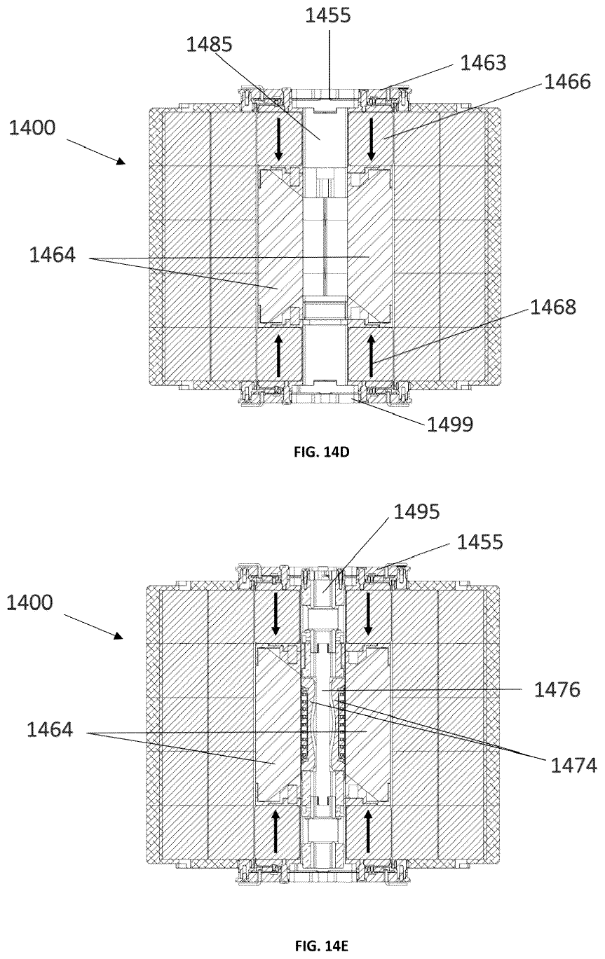

FIG. 14A shows an exploded perspective view of a magnet array 1400 including five magnet racks (1430, 1440, 1445, 1460 and 1470); a magnet-insert assembly 1455; and a central cavity assembly 1495. The central cavity assembly 1495 includes one or more pole pieces and a pole-piece positioner. The pole-piece positioner provides a holding structure (or framework) which receives the one or more pole pieces to form the central cavity assembly 1495. The pole-piece positioner may fix the one or more pole pieces in a certain position and/or orientation for insertion of the central cavity assembly 1495 into a shaft 1485 of the magnet-insert assembly 1455. Further, the pole-piece positioner may permit adjustments to be made to the position and/or orientation of the pole pieces by a user or actuator. Such adjustments may be made using one or more of a variety of actuators provided for that purpose, such as (but not limited to) screws, levers, sliders, tilting devices, goniometers, movable wedges, or the like.

Collectively, the central cavity assembly 1495 and the magnet-insert assembly 1455 may be inserted and/or removed from a central cavity 1465 in the magnet array 1400. The shape of the central cavity 1465 shown in FIG. 14A is just one example; the shape and size of the central cavity may be different than shown depending on the application for which the magnet-insert assembly and magnet array are intended.

During fabrication, the magnet-insert assembly 1455 may be inserted first into the central cavity 1465 and, second, the central cavity assembly 1495 may be inserted into the shaft 1485 of the magnet-insert assembly 1455, thereby installing both the magnet-insert assembly 1455 and the central cavity assembly 1495 into the magnet array 1400. Alternatively, during fabrication the central cavity assembly 1495 may be first inserted into the shaft 1485 of the magnet-insert assembly 1455. Then (second), the assembled structure (magnet-insert assembly 1455 plus central cavity assembly 1495) may be inserted all at once into the central cavity 1465 of the magnet array 1400. In FIG. 14A there is also shown a top cover 1488 and bottom cover 1489 affixed to the magnet array 1400 to enclose the component magnets in the magnet array 1400.

FIG. 14B shows a cross sectional view of magnet array 1400, the cross-section plane containing a longitudinal axis of the magnet array 1400. In FIG. 14B, the magnet-insert assembly 1455 and the central cavity assembly 1495 are both installed (positioned) in the central cavity of the magnet array 1400. FIG. 14C shows a side view of the magnet array 1400 from which the magnet-insert assembly 1455 can be seen protruding from the top and bottom of the magnet array 1400. FIG. 14D shows a cross-sectional side view of the magnet array 1400 including the magnet-insert assembly 1455. The magnet-insert assembly includes headstones 1464 which will be discussed further with respect to other Figures. The magnet-insert assembly includes a substructure having a cap 1463 and adapted to connect to a bottom plate 1499. The cap and the bottom plate are mirror images of one another. The bottom plate may be affixed to the base of the magnet array during fabrication of a magnetic resonance device and the bottom plate may be adapted to receive and secure the magnet-insert assembly (including the cap) into the magnet array via the central cavity.

It will be observed that headstones 1464 are tapered, with the narrow end of the taper pointed toward (proximal to) the shaft 1485. This tapered feature serves to focus the magnetic field provided by the magnets in the magnet array, so that the strength of the field within the central cavity can be much larger than it would be in the absence of the headstones (or, indeed, if the headstones were not configured in a tapered shape). It will be observed that certain permanent magnets 1466 (one of four of which is labeled in FIG. 14D), placed near the headstones 1464 and integrated within the magnet-insert assembly 1455, are magnetized axially (with magnetization vectors 1468), and this configuration of magnets and headstones further strengthens the available magnetic field.

In many magnetic resonance applications, spatial uniformity (homogeneity) and temporal stability are critical to the quality of the data that are gathered using a device such as the magnetic resonance apparatus of FIG. 8. The increased magnetic field strength of the combined tapered headstones 1464 and axially magnetized permanent magnets 1466 of the magnet-insert assembly 1455 of the disclosure allow the central cavity to be somewhat larger than it would be in the absence of the magnet-insert assembly at a chosen value of magnetic field. This permits the central cavity to comprise open spaces that can contain measures (such as thermal insulation, thermal sensors and/or heating elements) for more precise thermal control. In combination with the reduced temperature coefficients of typical soft ferromagnetic materials (relative to “hard,” high-coercivity materials like rare-earth magnets) this arrangement permits improved temporal stability of the magnetic field, both in normal operation of the magnetic resonance device and, equally important, during shimming and calibration operations.

The permanent magnets within the magnet-insert assembly may be of the same type or of a different type of component magnet as are used in the magnet racks of a rack stack in which the magnet-insert assembly is inserted. For instance, the permanent magnets 1466 may be of the same type as the axially magnetized hexagonal prismatic component magnets 1268 that are shown in FIG. 12E.

FIG. 14E shows a cross-sectional side view of the magnet array 1400 including the magnet-insert assembly 1455 and the central cavity assembly 1495. The central cavity assembly 1495 includes pole pieces 1474 and a positioner 1476.

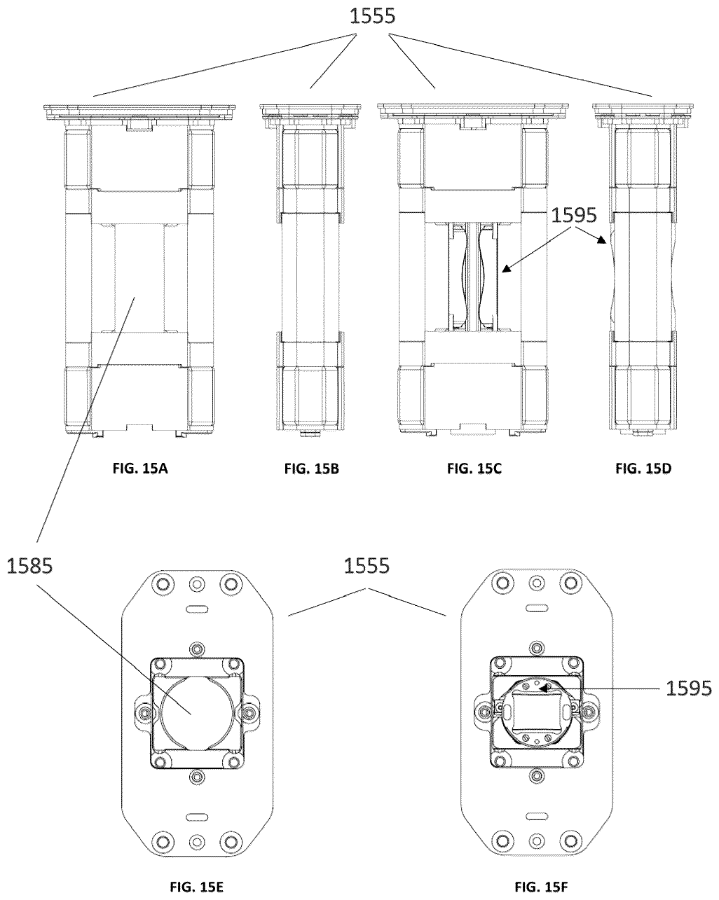

FIGS. 15A and 15B show two different side views of a magnet-insert assembly 1555. FIGS. 15C and 15D show two different side views of magnet-insert assembly 1555 and a central cavity assembly 1595 inserted into a shaft 1585 of magnet-insert assembly 1555. FIG. 15E shows a top view of the magnet-insert assembly 1555 and FIG. 15F shows a top view of the magnet-insert assembly 1555 with the central cavity assembly 1595 positioned therein.

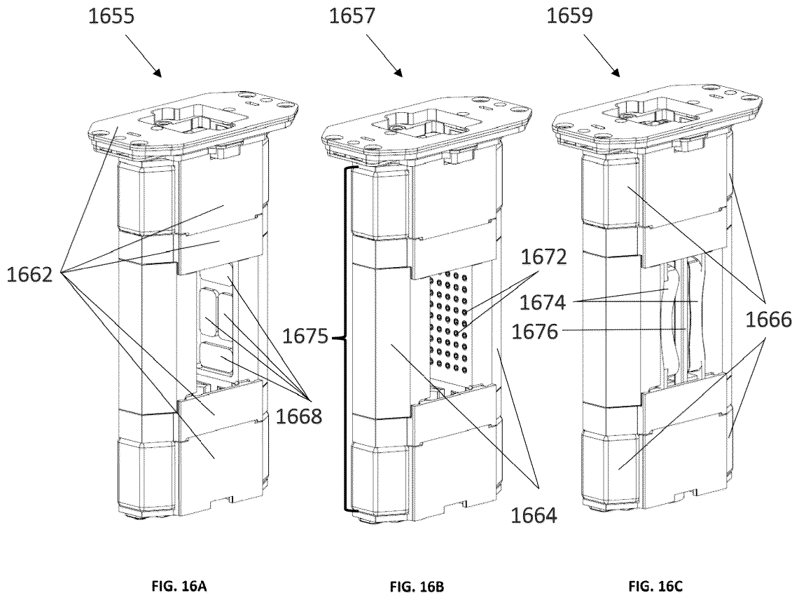

FIGS. 16A, 16B and 16C show perspective views of three examples of assembled magnet-insert assemblies 1655, 1657 and 1659, respectively. Although other substructures are possible and the examples in FIG. 16 are intended to be non-limiting, the same substructure 1662 is shown in each of FIGS. 16A, 16B and 16C (1662 is only labeled in FIG. 16A). Likewise, although alternative shapes, structures and configurations of magnet-insert assemblies are possible, in FIGS. 16A, 16B and 16C, the substructure 1662 is adapted to receive two headstones 1664 (labeled only in FIG. 16B) and four permanent magnets 1666 (labeled only in FIG. 16C). In FIGS. 16A, 16B and 16C, the headstones 1664 have a tapered shape and the permanent magnets 1666 are hexagonal prisms; however, other headstone and permanent magnet shapes are possible, including different tapering angles or configurations.

A surface formed by each headstone 1664 and the two permanent magnets 1666 (on each side of the magnet-insert assembly) is referred to as a sidewall 1675 which is labeled in FIG. 16B. Although in FIG. 16, each headstone and the two permanent magnets (on each side of the magnet-insert assembly) are substantially co-planar, this may not always be the case and the sidewall may have an uneven surface. The characteristics of the sidewall depend on the dimensions selected for the permanent magnets and the headstone, which further depend on the application of the magnet-insert assembly.

The magnet-insert assembly 1655 in FIG. 16A further includes eight tablets 1668, four of which are positioned on a front face of each of the two headstones 1664. Given the perspective shown in FIG. 16A, only four of eight tablets are shown; the other four of eight tablets are understood to be on the front face of the other headstone 1664, opposing the four tablets 1668 illustrated in FIG. 16A.

Alternatively, the magnet-insert assembly 1657 in FIG. 16B includes a pattern of apertures located on a front face of each of the two headstones 1664. In FIG. 16B, the apertures are threaded holes into which corresponding threaded inserts (screws) 1672 have been inserted. Other shapes, sizes and dimensions of apertures and inserts are also possible. During fabrication of the headstones 1664 and magnet-insert assembly 1657, the screws 1672 may be adjusted by threading (rotating) them into or out of the threaded holes. Given the perspective shown in FIG. 16B only one of two patterns of screws 1672 is shown; the other pattern of screws is understood to be on the front face of the other headstone 1664, opposing the pattern of screws 1672 illustrated in FIG. 16B.

In FIG. 16C, a central cavity assembly has been inserted into the magnet-insert assembly 1659. The central cavity assembly includes pole pieces 1674 and a positioner 1676.

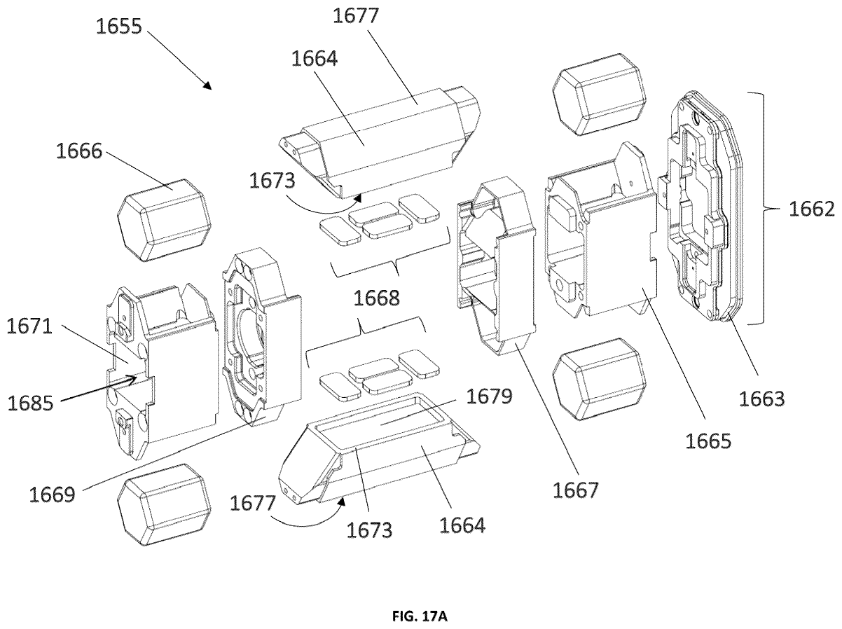

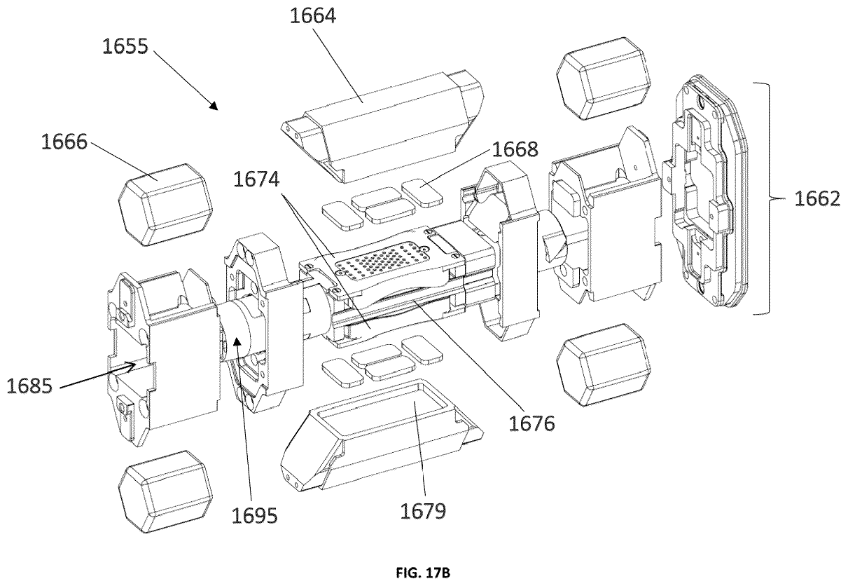

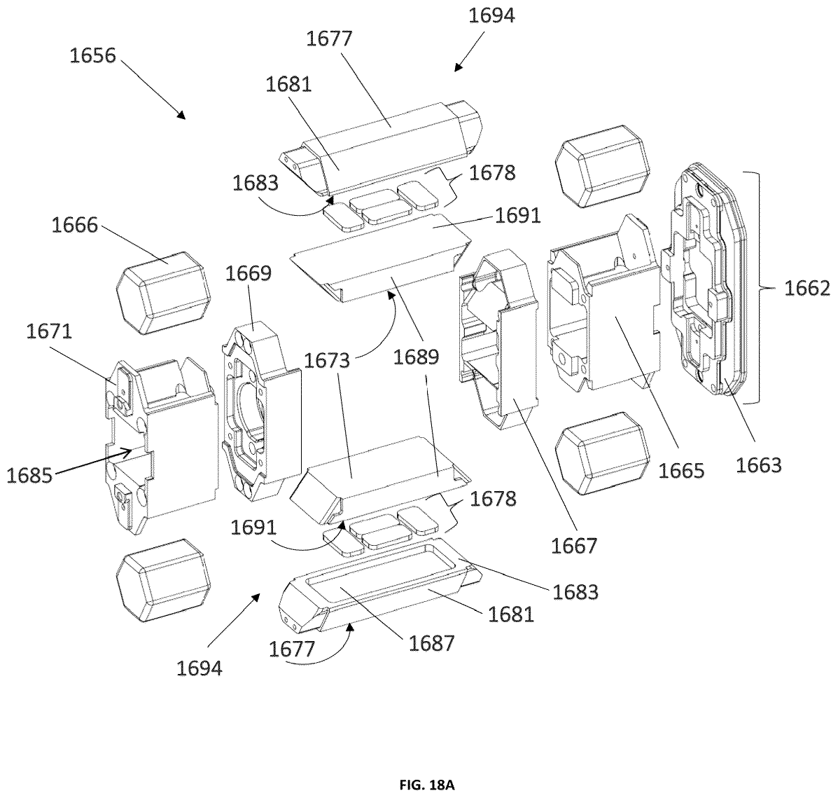

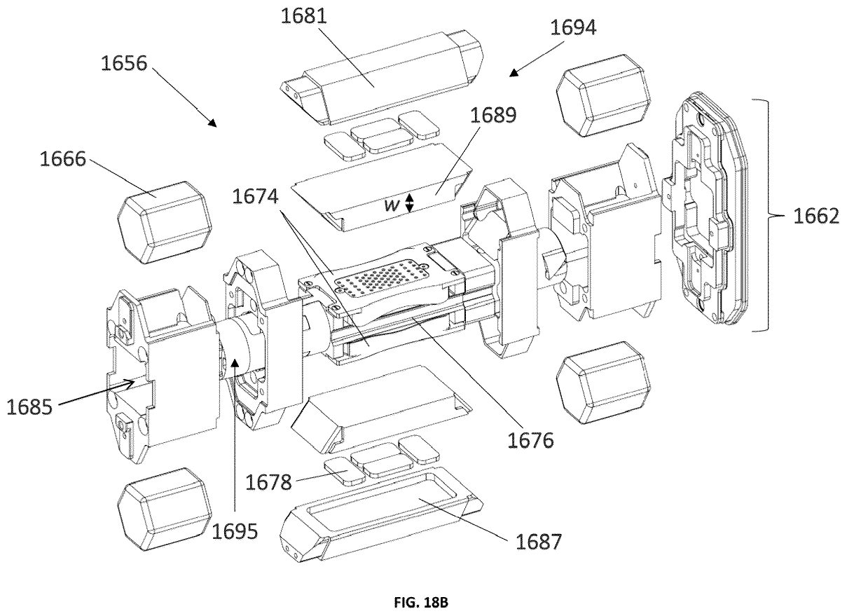

FIG. 17A shows an exploded perspective view of the magnet-insert assembly 1655 of FIG. 16A, including:
a substructure 1662 having five segments:
a cap 1663;
a top segment 1665;
a mid-upper segment 1667;
a mid-lower segment 1669; and
a bottom segment 1671;
and defining a shaft 1685 through the substructure 1662;
two headstones 1664, each having a front face 1673 and a rear face 1677;
four permanent magnets 1666 (only one is labeled in the FIG. 17A);
eight tablets 1668; and
a depression 1679 defined in the front face of each headstone 1664 (although only one depression is shown in FIG. 17A), the depressions for receiving the tablets during fabrication (assembly) of the magnet-insert assembly 1655.

In FIGS. 16-19, the following four segments of the substructure may be referred to as a substructure body: the top segment 1665, the mid-upper segment 1667, the mid-lower segment 1669, and the bottom segment 1671. In other words, the substructure 1662 is composed of a cap 1663 and a substructure body.

FIG. 17B shows an exploded perspective view of the magnet-insert assembly 1655 of FIG. 16A and FIG. 17A and a central cavity assembly 1695 positioned in the shaft 1685 of the magnet-insert assembly 1655. The central cavity assembly 1695 includes pole pieces 1674 and a positioner 1676. The mid-upper segment 1667 and the mid-lower segment 1669 of substructure 1662 receive and position the central cavity assembly 1695 in the shaft 1685 of the magnet-insert assembly 1655. The various components of the magnet-insert assembly, including the segments of the substructure, may be shaped or dimensioned differently depending on the application of the magnet-insert assembly or the magnet array or the magnetic resonance device in which the magnet-insert assembly may be used. Factors to be considered when determining the shape and dimensions of the various components of the magnet-insert assembly include mechanical stability and thermal insulation.

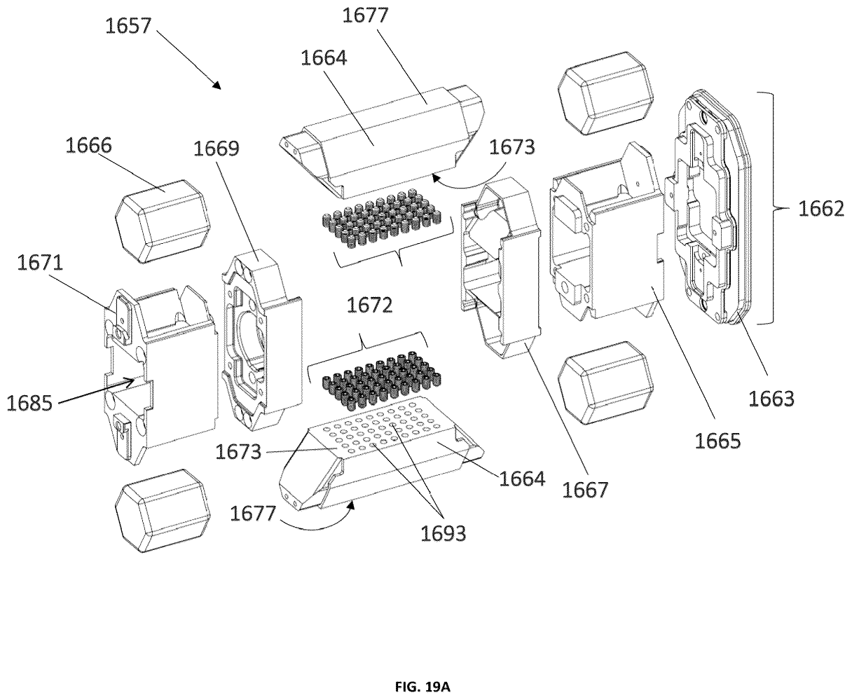

FIG. 18A shows an exploded perspective view of an alternative magnet-insert assembly 1656, including:
a substructure 1662 having five segments:
a cap 1663;
a top segment 1665;
a mid-upper segment 1667;
a mid-lower segment 1669; and
a bottom segment 1671;
and defining a shaft 1685 through the substructure 1662;
eight tablets 1678;
two headstones 1694, each having multiple parts:
a first part 1681, distal to the shaft 1685, and having a rear face 1677 and a front face 1683, the first part defining a depression 1687 in the front face 1683 (only one depression is visible in FIG. 18A); and
a second part 1689, proximal to the shaft 1685, and having a front face 1673 and a rear face 1691,
each depression 1687 for receiving four of eight of the tablets 1678 between the first part 1681 and the rear face 1691 of the second part 1689 of each of the two headstones 1694; and
four permanent magnets 1666 (only one is labeled in FIG. 18A).

FIG. 18B shows an exploded perspective view of the magnet-insert assembly 1656 of FIG. 18A and a central cavity assembly 1695 positioned in the shaft 1685 of the magnet-insert assembly 1656. The central cavity assembly 1695 includes pole pieces 1674 and a positioner 1676. The mid-upper segment 1667 and the mid-lower segment 1669 of substructure 1662 receive and position the central cavity assembly 1695 in the shaft 1685 of the magnet-insert assembly 1656. The various components of the magnet-insert assembly, including the segments of the substructure, may be shaped or dimensioned differently depending on the application of the magnet-insert assembly or the magnet array or the magnetic resonance device in which the magnet-insert assembly may be used. Factors to be considered when determining the shape and dimensions of the various components of the magnet-insert assembly include mechanical stability and thermal insulation.

In the foregoing two example embodiments, tablets are used to change the degree to which the magnetic material comprising, within, and on the surface of the headstone can shape or modify the magnetic field inside the gap (space) between the front faces of the headstones. Placing the tablets on the front faces of the headstones locates the tablets closer to the region wherein the field is to be modified. Placing the tablets within a multi-part headstone locates the tablets further away from that region. There is a tradeoff in efficacy with this choice—having the tablets closer gives the user a stronger effect on the field, but at the cost of coarser finesse in light of mechanical and magnetic tolerances in fabricating the tablets, while having the tablets further away gives the user more finesse and control at the cost of reduced magnetic strength, and at the further cost of more complexity in manufacturing associated with a multi-part headstone structure.

In the present disclosure, a headstone may have one or more parts that have the same or different widths. For clarity, in FIG. 18B, the width dimension is denoted by the letter w as shown on the second part 1689 of the headstone 1694.

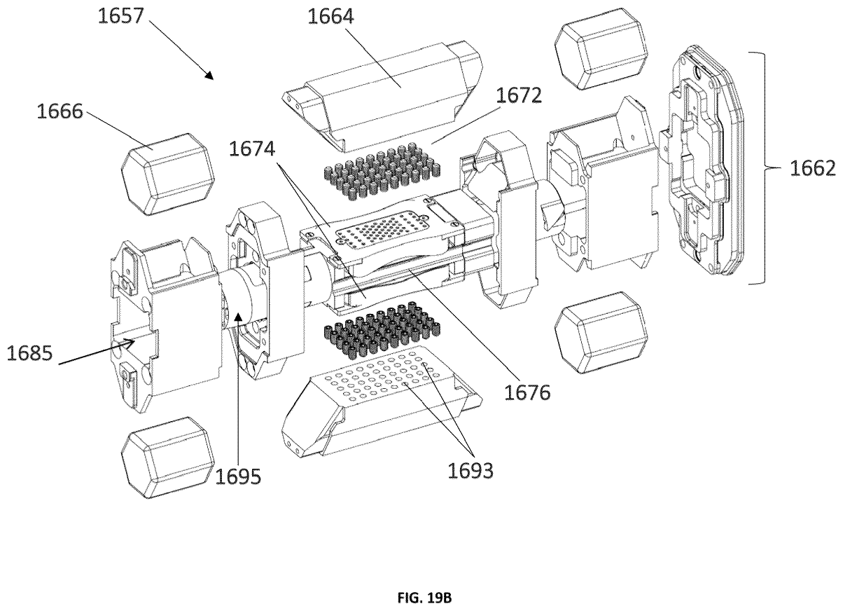

FIG. 19A shows an exploded perspective view of the magnet-insert assembly 1657 of FIG. 16B, including:
a substructure 1662 having five segments:
a cap 1663;
a top segment 1665;
a mid-upper segment 1667;
a mid-lower segment 1669; and
a bottom segment 1671;
and defining a shaft 1685 through the substructure 1662;
two headstones 1664, each having a front face 1673 and a rear face 1677;
four permanent magnets 1666 (only one is labeled in the FIG. 19A);
a pattern of apertures 1693 defined in the front face 1673 of each of the two headstones 1664; and
threaded inserts (screws) 1672;
the apertures 1693 for receiving the screws 1672 during fabrication (assembly) of the magnet-insert assembly 1657.

FIG. 19B shows an exploded perspective view of the magnet-insert assembly 1657 of FIG. 16B and FIG. 19A and a central cavity assembly 1695 positioned in the shaft 1685 of the magnet-insert assembly 1657. The central cavity assembly 1695 includes pole pieces 1674 and a positioner 1676. The mid-upper segment 1667 and the mid-lower segment 1669 of substructure 1662 receive and position the central cavity assembly 1695 in the shaft 1685 of the magnet-insert assembly 1657. The various components of the magnet-insert assembly, including the segments of the substructure, may be shaped or dimensioned differently depending on the application of the magnet-insert assembly or the magnet array or the magnetic resonance device in which the magnet-insert assembly may be used. Factors to be considered when determining the shape and dimensions of the various components of the magnet-insert assembly include mechanical stability and thermal insulation.

A method of assembling a magnet-insert assembly and a central cavity assembly into a magnet rack stack may comprise the following steps:
a) populating one or more magnet racks with component magnets;
b) if there is more than one magnet rack, stacking and securing together the magnet racks to produce a magnet rack stack, wherein the arrangement of the component magnets in the magnet rack or magnet rack stack defines a central cavity in the magnet rack or magnet rack stack;
c) affixing a bottom plate to a bottom rack of the magnet rack stack;
d) providing a substructure having multiple segments including a cap;
e) assembling the multiple segments into the substructure which defines a shaft therein;
f) arranging and securing one or more headstones and one or more permanent magnets in the substructure to produce a magnet-insert assembly;
g) inserting the magnet-insert assembly into the central cavity of the magnet rack or magnet rack stack and connecting a bottom segment of the substructure of the magnet-insert assembly to the bottom plate; and
h) assembling and inserting a central cavity assembly including one or more pole pieces through the cap and into the shaft of the magnet-insert assembly.

The method described above may comprise affixing a bottom plate to a bottom rack of the rack stack (step c) before stacking and securing together the magnet racks (step b). The method described above may comprise arranging and securing the one or more permanent magnets in the substructure before or after arranging and securing the one or more headstones in the substructure (see step f). The method described above may comprise arranging and securing the one or more permanent magnets and/or the one or more headstones in the segments of the substructure before (step e of) assembling the multiple segments into the substructure. The method described above may comprise assembling and inserting a central cavity assembly including one or more pole pieces through the cap and into the shaft of the magnet-insert assembly (step h) before inserting the magnet-insert assembly into the central cavity of the magnet rack stack and connecting a bottom segment of the substructure of the magnet-insert assembly to the bottom plate (step g).

In the example embodiments comprising tablets (FIGS. 17A-18B), the magnetic field may be shaped or modified (shimmed) by changing the configuration of tablets. The tablets are magnetized by the magnet array, and their magnetization produces changes to the magnetic field configuration within the central cavity. These changes can be modeled in magnetostatic simulations or measured with field mapping techniques, and so then changes in the number, placement, and magnetic permeability of the tablets effects a shimming capability of the tablets. In the example embodiment of FIGS. 19A-B, this capability is provided instead by the presence, absence, number, placement, and magnetic permeability of the threaded inserts (screws) 1672. In particular, the shimming capability is provided by screwing individual threaded inserts into or out of the apertures 1693 to reposition the threaded inserts relative to the location of other objects in the central cavity, such as a sample under study, or by removing some, or by replacing some threaded inserts with inserts having higher or lower permeability.

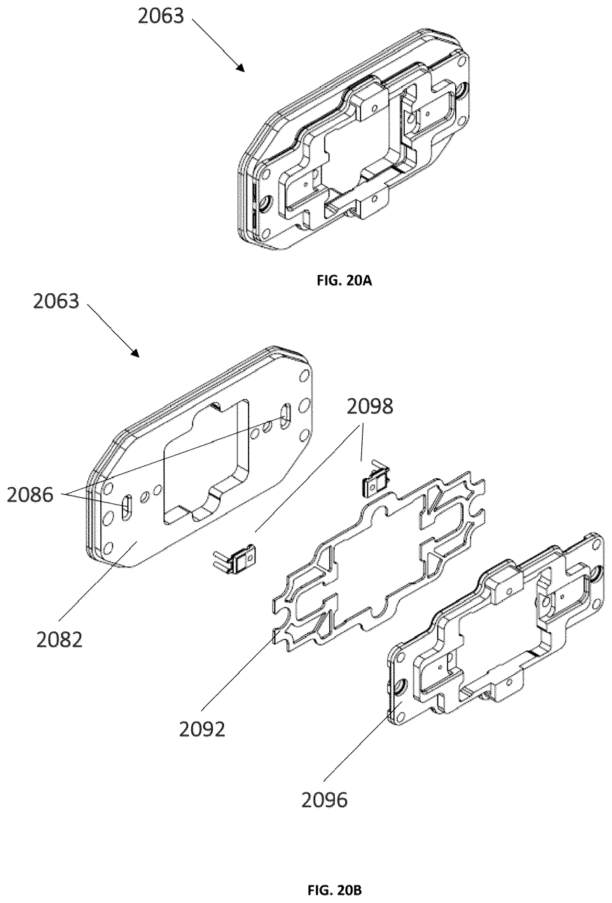

FIG. 20A and FIG. 20B show a perspective view of an assembled cap 2063 of a substructure of a magnet-insert assembly and an exploded view of the cap 2063, respectively. As shown in FIG. 20B, the cap 2063 in this example is composed of multiple parts: a magnetically shielded layer 2082, a thermally insulating layer 2092, a thermally conductive layer 2096, and two resistors 2098. The same layered structure of the cap may be utilized in the corresponding bottom plate (e.g., 1499 in FIG. 14D).

In embodiments of the disclosure, the substructure's cap serves the purpose of shielding the permanent magnets (e.g., 1666 in FIGS. 16-19) within the magnet-insert assembly from (1) magnetic interaction with objects outside a magnet array into which the magnet-insert assembly is inserted and (2) fluctuations in temperature. Both of these physical phenomena can reduce the efficacy of a magnetic resonance device in which the magnet array is employed. To these ends, in embodiments, the magnetically shielded layer (2082 in FIG. 20B) is made of a soft (magnetically permeable) magnetic material suitable for confining magnetic flux, such as steel alloys, hiperco, nickel, or other magnetic iron, cobalt, or nickel alloys or alloys containing other metals. The thermally conductive layer 2096 may be made of a suitable strong and thermally conductive material such as, without limitation, aluminum or alloys thereof. The thermally insulating layer 2092 serves the purpose of delivering and homogenizing Joule heat (Ohmic heat) provided by resistors 2098 to the permanent magnets 1666 when current is applied to the resistors 2098 through wires (not shown) which are connected to the resistors through access holes 2086 in the magnetically shielded layer 2082. Insulating layer 2092 helps to control this Joule heat by confining the heat near the magnets 1666 in the magnet-insert assembly. Suitable insulating materials are for example, any of a variety of ceramic or plastic materials, such as Delrin, ABS (acrylonitrile butadiene styrene) or Teflon. Sometimes the insulating layer may be referred to as a gasket.

The thermally conductive layer 2096, which is proximal to the top segment 1665 of substructure 1662 shown in FIGS. 17-19, is the layer through which the top segment 1665 is mounted and positioned in the substructure. Likewise, the corresponding bottom plate (e.g., 1499 shown in FIG. 14D) has a thermally conductive layer which is proximal to the bottom segment (e.g., 1671 of substructure 1662). The magnet-insert assembly is connected (e.g., using screws or other fixtures or fixturing materials) through the bottom segment to the thermally conductive layer of the bottom plate to secure the magnet-insert assembly in the central cavity of the magnet array.

The different parts of the substructure, including the layers of the cap and the layers of the bottom plate, may be affixed together with screws or other mechanical fixtures or fixturing materials. The headstones 1664, as shown in FIGS. 17-19, are secured between the mid-upper segment 1667 and the mid-lower segment 1669 within the substructure 1662 by screws. The permanent magnets 1666 are affixed to the top segment 1665 and the bottom segment 1671 of the substructure 1662 by glue. The tablets 1668 are affixed in the depression 1679 of the headstone 1664 by glue. However, in alternative embodiments any mechanical fixture or fixturing material such as a glue or other adhesive may be used to connect the components of the magnet-insert assembly to one another.

While preferred embodiments have been described above and illustrated in the accompanying drawings, it will be evident to those skilled in the art that modifications may be made without departing from this disclosure. Such modifications are considered as possible variants comprised in the scope of the disclosure.

1. A magnet-insert assembly adapted for insertion into and removal from a central cavity in a magnetic-field generating magnet array, the magnet-insert assembly comprising:
a substructure defining a shaft therein;
one or more headstones; and
one or more permanent magnets;
the substructure adapted to receive, secure and position the one or more headstones and the one or more permanent magnets in the central cavity of the magnet array.

2. The magnet-insert assembly of claim 1, comprising two headstones and four permanent magnets, the four permanent magnets each having a hexagonal prismatic shape.

3. (canceled)

4. (canceled)

5. The magnet-insert assembly of claim 1, the substructure having five segments:
a cap;
a top segment;
a mid-upper segment;
a mid-lower segment; and
a bottom segment.

6. The magnet-insert assembly of claim 1, the shaft adapted to receive a central cavity assembly comprising one or more pole pieces and a pole piece positioner.

7. The magnet-insert assembly of claim 1, further comprising one or more pieces of magnetically permeable material, magnetic polarization of which, when inserted into the magnet array, modifies a magnetic field generated by the magnet array.

8. The magnet-insert assembly of claim 7, wherein the one or more pieces of magnetically permeable material are tablets or inserts.

9. The magnet-insert assembly of claim 2, each of the two headstones comprising a rear face and a front face.

10. The magnet-insert assembly of claim 9, further comprising one or more tablets.

11. The magnet-insert assembly of claim 10, each front face defining a depression adapted to receive the one or more tablets.

12. (canceled)

13. (canceled)

14. The magnet-insert assembly of claim 10, each of the two headstones comprising multiple parts.

15. The magnet-insert assembly of claim 14, each of the two headstones comprising two cooperating parts, a first part, distal to the shaft, and a second part, proximal to the shaft, and a front face of the first part defining a depression adapted to receive the one or more tablets.

16. The magnet-insert assembly of claim 9, each front face defining a plurality of apertures adapted to receive inserts.

17. (canceled)

18. The magnet-insert assembly of claim 5, the cap comprising:
a magnetically shielded layer;
a thermally insulating layer; and
a thermally conductive layer.

19. A magnet array comprising a plurality of magnet racks, the magnet array defining a central cavity adapted to receive a removable magnet-insert assembly comprising:
a substructure defining a shaft therein;
one or more headstones; and
one or more permanent magnets;
the substructure adapted to receive, secure and position the one or more headstones and the one or more permanent magnets in the central cavity of the magnet array.

20. The magnet array of claim 19, the shaft adapted to receive a central cavity assembly comprising one or more pole pieces and a pole piece positioner.

21. The magnet-insert assembly of claim 1, wherein:
the substructure comprises a cap and a substructure body;
at least one headstone is aligned with at least one permanent magnet to define a sidewall with the at least one permanent magnet; and
the shaft extends through the cap and the substructure body parallel to the sidewall.

22. The magnet-insert assembly of claim 21, wherein the at least one headstone is aligned with and provided in between two permanent magnets to define the sidewall with the two permanent magnets.

23. The magnet-insert assembly of claim 22, wherein each of two headstones are provided in between two permanent magnets to define a separate sidewall whereby the magnet-insert assembly comprises two sidewalls and the two sidewalls are symmetrically provided with respect to the shaft.

24. A magnetic resonance device comprising the magnet array of claim 19.

25. A method for assembling a magnet-insert assembly, comprising:
providing a substructure defining a shaft therein; and
arranging one or more headstones and one or more permanent magnets in the substructure.

26. A method for assembling a magnet array, comprising:
providing a first plurality of polyhedral magnets;
arranging the first plurality of polyhedral magnets in a Halbach cylinder configuration in a magnet rack, centers of individual ones of the first plurality of polyhedral magnets being arranged substantially in a plane in the magnet rack, the first plurality of polyhedral magnets at least partly enclosing a central cavity in the magnet array;
providing a second plurality of polyhedral magnets;
arranging the second plurality of polyhedral magnets in a non-Halbach cylinder configuration in the magnet rack;
providing a plurality of truncated polyhedral magnets;
arranging the plurality of truncated polyhedral magnets in closest proximity to the central cavity; and
arranging the magnet rack in a rack stack to assemble the magnet array.

27. The magnet array of claim 19, wherein each of the plurality of magnet racks comprises a cell framework surrounding the central cavity, the cell framework defining a plurality of lattice sites for receiving a plurality of magnets;
wherein centers of the magnets occupying said lattice sites are arranged in a hexagonal Bravais lattice configuration;
wherein the lattice sites define a plurality of concentric rings around the central cavity;
wherein a shape of the central cavity is defined by the lattice sites of at least an innermost ring and a second innermost ring; and
wherein a surface of each of a subset of magnets in the innermost ring is truncated.
